(19) United States
(12) Patent Application Publication
(10) Pub. No.: US 2012/0111994 A1
(43) Pub. Date: May 10, 2012

(54) CROSS-FLOW FAN PROPULSION SYSTEM

(75) Inventors: Joseph Kummer, Fayetteville, NY (US); Jimmie B. Allred, III, Skaneateles, NY (US)

(73) Assignee: PROPULSIVE WING, LLC, Elbridge, NY (US)

(21) Appl. No.: 13/006,932

(22) Filed: Jan. 14, 2011

Related U.S. Application Data
(60) Provisional application No. 61/295,339, filed on Jan. 15, 2010.

(51) Int. Cl. B64C 15/02; B23P 15/00; H05K 13/00; F01D 5/12; B64C 15/00; B63G 8/08; F01D 5/14; F01D 1/06

(52) U.S. Cl. 244/15; 416/178; 29/889.7; 415/203; 416/20 R; 114/337; 29/592.1

(57) ABSTRACT

The present invention includes improvements to cross-flow fans and cross-flow fan propelled aircraft including improved control, a dynamically adjustable vortex wall and internal housing, a vortex tube, vertical takeoff and landing rotorcraft configurations, the inclusion of an optimized oscillating blade fan, a wavy vortex wall, power plant refinements, dual leading and trailing edge configurations, stability improvements, tip plates, tapered wings, tapered fans, a fan construction method, and underwater applications.

### REFERENCE TO RELATED APPLICATIONS

This application claims one or more inventions which were disclosed in Provisional Application No. 61/295,339, filed Jan. 15, 2010, entitled “Improved Cross-Flow Fan Propulsion System”. The benefit under 35 USC §119(e) of the U.S. provisional application is hereby claimed, and the aforementioned application is hereby incorporated herein by reference.

### BACKGROUND OF THE INVENTION

1. Field of the Invention

This invention relates to cross-flow fans and cross-flow fan propelled vehicles.

2. Description of Related Art

The cross-flow fan (CFF), first disclosed in 1893 in U.S. Pat. No. 507,445 (Mortier), incorporated herein by reference, is used extensively in tower fans, air conditioners, and many other products throughout the heating and ventilation (HVAC) industry. The fan is usually long in relation to the diameter, so the flow approximately remains 2-dimensional (2D) away from the ends. The cross-flow fan uses an impeller with forward curved blades, placed in a housing with a rear wall and vortex wall. Unlike radial machines, the main flow moves transversely across the impeller, passing the blading twice. The popularity of the cross-flow fan in the HVAC industry comes from its compactness, shape, quiet operation, and ability to provide a high pressure coefficient. Effectively a rectangular fan in terms of inlet and outlet geometry, the diameter readily scales to fit the available space, and the length is adjustable to meet flow rate requirements for the particular application. Many improvements have been made to the cross-flow fan, including those disclosed in U.S. Pat. No. 3,033,411 (Coaster) and U.S. Pat. No. 3,096,931 (Eck), both incorporated herein by reference.

In addition to HVAC products, since the flow both enters and exits the impeller radially, the cross-flow fan is well suited for aircraft applications. Due to the 2D nature of the flow, the fan readily integrates into a wing for use in both thrust production and boundary layer control.

Historically, several companies, universities, and individuals have attempted to utilize cross-flow fan propulsion in aircraft; however, most previous attempts met with little or no success due to an inadequate understanding of the flow physics and improper housing design and fan placement. U.S. Pat. No. 3,065,928 (Dornier), incorporated herein by reference, disclosed an aircraft design that used cross-flow fans embedded within the middle of a conventional airplane wing. Three years later, U.S. Pat. No. 3,178,131 (Laing), incorporated herein by reference, disclosed an aircraft wing structure that utilized fully embedded cross-flow fans located near the trailing edge of a conventional wing.

While at Lockheed Corporation, Hancock proposed distributing fully embedded cross-flow fans near the trailing edge of a conventional transport aircraft, with shafts and couplings connecting them to wing-tip and root-mounted gas turbines, (Hancock, J. P., “Test of a High Efficiency Transverse Fan,” AIAA/SAE/ASME 16th Joint Propulsion Conference, AIAA-80-1243, Hartford, Conn., 1980, incorporated herein by reference). The design proposed to duct air into the cross-flow fan from both wing surfaces. This design, however, limited the fan size and ducting.

In the late 1970s and 1980s, a series of work at the University of Texas at Arlington investigated the use of cross-flow fans for propulsion and flow control, as disclosed in Harloff, Gary J., “Cross-Flow Fan Experimental Development and Finite-Element Modeling,” Ph.D. Dissertation, University of Texas at Arlington, Arlington, Tex., 1979; Chawla, Kalpana, “Optimization of Cross Flow Fan Housing for Airplane Wing Installation,” M.S. Thesis, University of Texas at Arlington, Arlington, Tex., 1984; Lin, Chia-Hong, “A Wind Tunnel Investigation of the External Aerodynamics of an Airfoil with an Internal Cross Flow Fan,” M.S. Thesis, University of Texas at Arlington, Arlington, Tex., 1986; and Nieh, Ting-Wen, “The Propulsive Characteristics of a Cross Flow Fan Installed in an Airfoil” M.S. Thesis, University of Texas at Arlington, Arlington, Tex., 1988, all herein incorporated by reference.

Harloff, in conjunction with Vought Corporation, performed a series of experiments to test the operation of the cross-flow fan at very high rotation speeds (up to 12,500 rpm). As a follow-on to Harloff's work, Chawla performed a series of wind-tunnel tests which demonstrated the use of a cross-flow fan for boundary layer control through boundary layer blowing. By locating a cross-flow fan within the middle of a thick airfoil, flow was ducted from the airfoil pressure surface, through the fan, and exhausted over the suction surface as a jet. This increased the maximum lift coefficient by delaying stall at high angle of attack, but failed to produce adequate thrust for propulsion. Two subsequent studies attempted to use flow drawn into the fan from the leading edge and expelled over the suction surface to provide both thrust and circulation control. These configurations were unsuccessful, however, due to improper housing design.

More recently, a design called the FanWing was disclosed in U.S. Pat. Nos. 6,231,004 and 6,527,229 (Peebles), herein incorporated by reference. This configuration utilizes a cross-flow fan in the manner of a leading edge spinning cylinder to produce a thrust to propel the plane forward and high Magnus force for lift. This configuration is similar to the rotating leading edge cylinder designs of the 1950s.

U.S. Pat. No. 6,016,992 (Kolacny), herein incorporated by reference, discloses a short takeoff and landing vehicle with a fuselage and a cross-flow fan and fan inlet located near the leading edge of a wing. In this invention, an airfoil shape is used both below and above the fan to form the surfaces of the air intake duct. U.S. Pat. No. 6,261,051 (Kolacny), herein incorporated by reference, also discloses a specific cross-flow fan housing geometry.

U.S. Pat. No. 4,702,437 (Stearns), incorporated herein by reference, discloses a helicopter rotor with a cross-flow fan embedded within the rotor near the blade tip. Here, air is drawn into the fan through a slot at the leading edge of the blade. The fan provides thrust to rotate the helicopter blades.

U.S. Pat. No. 5,449,271 (Bushnell), incorporated herein by reference, discloses a J-shaped vortex wall with varying impeller clearance and setting angle.

### SUMMARY OF THE INVENTION

Several aspects of cross-flow fan propulsion are improved. The propulsion system includes a combined propulsor, flow control device, and cargo-carrying platform with large thickness-to-chord ratio cross-section (ranging from 20% up to 50% or more), which provides a compact, cost-effective short takeoff and landing (STOL) or vertical takeoff and landing (VTOL) solution. With its unique thick-wing design, the cross-flow propulsion mechanism within a distributed cross-flow fan wing can carry 3 times the payload weight and 10 times the internal payload volume of conventional systems. For this reason, the aircraft is considered an aerial utility vehicle, or AUV. The platform is also highly maneuverable, generates low noise, and offers a high degree of user safety due to the elimination of external rotating propellers.

The present invention includes several improvements to cross-flow fan propulsion technology, including improved control, a dynamically adjustable vortex wall and internal housing, a vortex tube, vertical takeoff and landing rotorcraft configurations, the inclusion of an optimized oscillating blade fan, a wavy vortex wall, power plant refinements, dual leading and trailing edge configurations, stability improvements, tip plates, tapered wings, tapered fans, a fan construction method, and underwater applications.

### BRIEF DESCRIPTION OF THE DRAWINGS

FIG. 1a shows a cross-flow fan wing in an embodiment of the present invention.

FIG. 1b shows thrust deflectors of the cross-flow fan wing of FIG. 1a.

FIG. 2 shows a schematic of the cross-flow fan internal duct geometry.

FIG. 3 shows circumferential adjustment of the vortex wall.

FIG. 4 shows radial adjustment of the vortex wall.

FIG. 5 shows control of the internal fan housing geometry.

FIG. 6 shows adjustment of the duct inlet and outlet flaps.

FIG. 7 shows a schematic of a vortex tube.

FIG. 8a shows a vortex tube installed in a cross-flow fan wing.

FIG. 8b shows another view of the vortex tube installed in a cross-flow fan wing.

FIG. 9 shows a vacuum from the fan vortex drawing gas or liquid into the fan from a tank.

FIG. 10a shows control via actuated panels located on the cross flow fan housing shroud.

FIG. 10b shows another view of control via actuated panels located on the cross flow fan housing shroud.

FIG. 11 shows a cross flow fan wing with independently driven fans.

FIG. 12a shows a helicopter vertical lift configuration for a cross-flow propulsion mechanism.

FIG. 12b shows a close-up view of the cross-flow propulsion mechanism shown in FIG. 12a.

FIG. 13 shows a vertical lift cross-flow fan wing configuration.

FIG. 14 shows another vertical lift cross-flow fan wing configuration.

FIG. 15a shows a helicopter configuration with a distributed cross-flow fan wing rotor and a standard fuselage.

FIG. 15b shows another view of the helicopter configuration of FIG. 15a.

FIG. 16a shows the distributed cross-flow fan wing rotor locked in horizontal flight mode.

FIG. 16b shows another view of the distributed cross-flow fan wing rotor locked in horizontal flight mode.

FIG. 17a shows a schematic of an oscillating blade fan for use in a cross-flow propulsion mechanism system.

FIG. 17b shows another view of the oscillating blade fan of FIG. 17a.

FIG. 18a shows a square-wave geometry wavy vortex wall.

FIG. 18b shows another view of the square-wave geometry wavy vortex wall of FIG. 18a.

FIG. 19a shows a sine-wave geometry wavy vortex wall.

FIG. 19b shows another view of the sine-wave geometry wavy vortex wall of FIG. 19a.

FIG. 20 shows a drive configuration with multiple motors and pulleys.

FIG. 21a shows a drive configuration with a single motor and pulley driving multiple fans.

FIG. 21b shows a close up view of the drive configuration of FIG. 21a.

FIG. 22 shows a motor or engine mounted in between two cross-flow fans.

FIG. 23a shows another embodiment of the current invention with a single motor driving two cross-flow fans.

FIG. 23b shows another view of the embodiment shown in FIG. 23a.

FIG. 24a shows a schematic of a Turbo-cross-flow fan propulsion system.

FIG. 24b shows a view of the top of the Turbo-cross-flow fan propulsion system of FIG. 24a.

FIG. 25 shows another embodiment of a Turbo-cross-flow fan propulsion system integrated into a vehicle.

FIG. 26a shows a combination leading and trailing edge distributed cross-flow fan wing.

FIG. 26b shows another view of FIG. 26a.

FIG. 27a shows a combination leading and trailing edge distributed cross-flow fan wing configuration in a vertical takeoff and landing configuration.

FIG. 27b shows another view of FIG. 27a.

FIG. 28 shows a combination leading and trailing edge distributed cross-flow fan wing configuration in a cruise configuration.

FIG. 29a shows a front view distributed cross-flow fan wing with sweep, dihedral, and taper added to the forward section of the wing.

FIG. 29b shows a top down view of FIG. 29a.

FIG. 30 shows a tapered cross-flow fan.

FIG. 31 shows a cross-flow fan constructed from pultruded carbon-fiber blades and carbon-fiber support plates.

### DETAILED DESCRIPTION OF THE INVENTION

U.S. Pat. No. 7,641,144, incorporated herein by reference, describes an aerodynamic platform that integrates an embedded, distributed cross-flow fan propulsion system within a thick wing.

The cross-flow fan propulsion systems described herein can be used in both aircraft and underwater applications. Cross-flow fans, partially embedded within a wing, draw flow in from the wing suction surface and exhaust the flow out at the trailing edge. The fans can be powered by any motor or engine. The cross-flow fan propulsive system has the ability to draw in substantial amounts of air and maintain attached flow, allowing operation at angles of attack up to 60 degrees and lift coefficients of more than 10 at takeoff and landing for extremely short ground roll. In cruise, the combination of distributed boundary-layer ingestion and wake filling increase propulsive efficiency, while distributed vectored thrust provides substantial improvements in pressure drag.

The propulsion systems described herein preferably include a combined propulsor, flow control device, and cargo-carrying platform with large thickness-to-chord ratio cross-section. The thickness-to-chord ratio cross section preferably ranges from approximately 20% to 50%. In one preferred embodiment, the thickness-to-chord ratio cross section is approximately 20%. In another preferred embodiment, the thickness-to-chord ratio cross section is approximately 25%. In yet another preferred embodiment, the thickness-to-chord ratio cross section is 50% or more. The propulsion system provides a compact, cost-effective short takeoff and landing (STOL) or vertical takeoff and landing (VTOL) solution. With its unique thick-wing design, the cross-flow propulsion mechanism within a distributed cross-flow fan wing can carry 3 times the payload weight and 10 times the internal payload volume of conventional systems. For this reason, the aircraft is considered an aerial utility vehicle, or AUV. The platform is also highly maneuverable, generates low noise, and offers a high degree of user safety due to the elimination of external rotating propellers.

This technology may be particularly useful in a new unmanned aircraft to serve commercial and military markets, with particular emphasis on applications requiring large internal volume, heavy load-carrying capability, short or vertical takeoff and landing, and high speed cruise.

The present invention includes several improvements to cross-flow fan propulsion technology, including improved control, a dynamically adjustable vortex wall and internal housing, a vortex tube, vertical takeoff and landing rotorcraft configurations, the inclusion of an optimized oscillating blade fan, a wavy vortex wall, power plant refinements, dual leading and trailing edge configurations, stability improvements, tip plates, tapered wings, tapered fans, a fan construction method, and underwater applications.

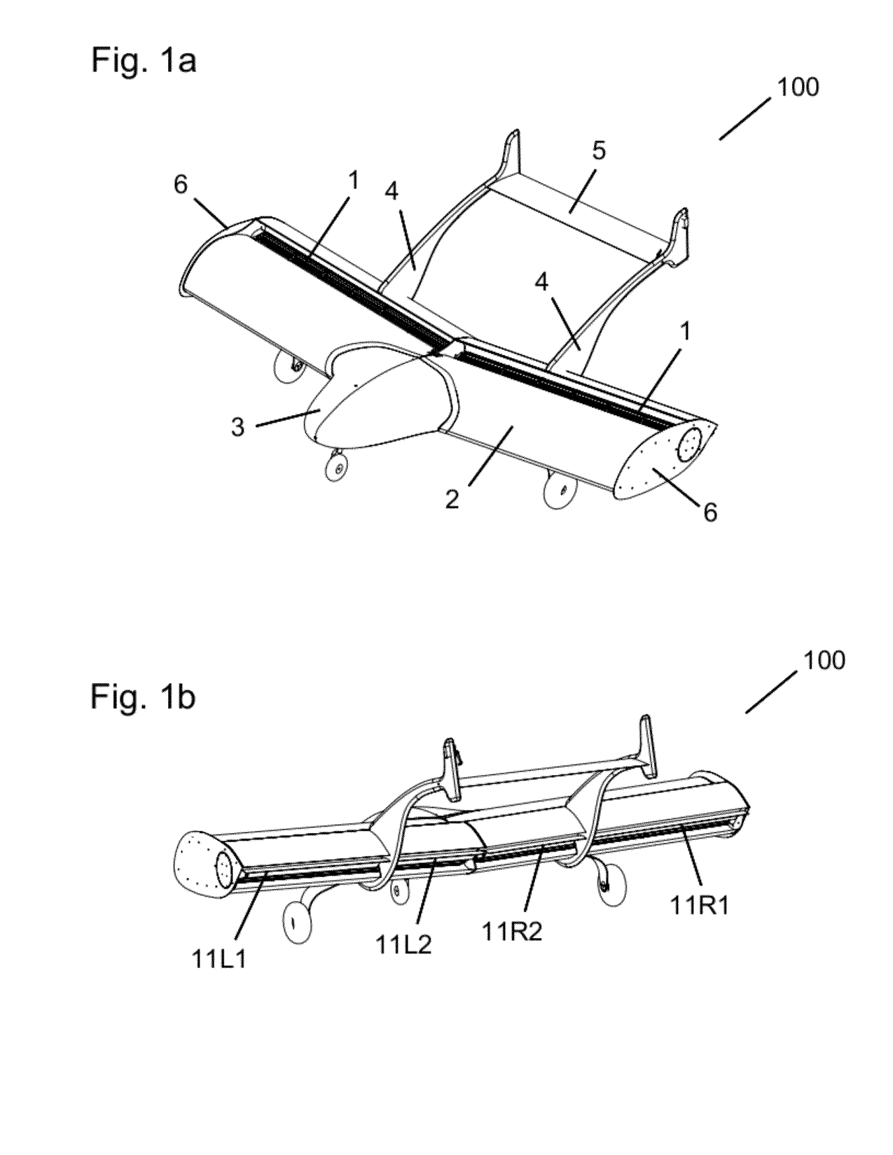

Using the vectored thrusting capabilities of the distributed cross-flow fan wing design, unique opportunities exist for control of an aircraft. In particular, by using collective and differential vectored thrust, pitch and roll degrees of freedom can be controlled. One embodiment of a cross-flow fan wing system or vehicle 100 is shown in FIGS. 1a and 1b. Wing 100 is comprised of one or more cross-flow fans 1, a main wing body 2, which is preferably airfoil-shaped, a nose 3, one or more tail booms 4, a tail surface 5, and wing tip plates 6. By including multiple thrust deflectors 11L1, 11L2, 11R1 and 11R2 spanwise along the wing, pitch and roll can be controlled independently through superposition of the control surface actuation. For example, vectored thrust downward increases the airfoil circulation, thus increasing lift. If thrust deflectors 11 are vectored downward on one side of the airplane and upward (or less downward) on the opposite side, the resulting unbalanced forces will create a rolling moment. As an example in the figure, thrust deflectors 11L1 and 11L2 could be vectored downward while thrust deflectors 11R1 and 11R2 are vectored upward (or less downward). This action allows for roll control of the aircraft.

Simultaneously, vectored thrust downward also increases the nose-down pitching moment. Vectored thrust upward has the opposite effect: decreased circulation, decreased lift, and increased nose-up pitching moment. If thrust deflectors 11 are all vectored upward or downward together simultaneously, a pitching moment results. A downward deflection of the thrust deflectors 11 results in a nose-down pitching moment, while an upward deflection of the thrust deflectors 11 results in a nose-up pitching moment.

Pitching and rolling control are available simultaneously through a superposition of these two control methods. For example, if all four flaps move upward or downward together, this controls pitch. If the thrust deflectors 11 on the left-hand side of the plane move upward and the thrust deflectors 11 on the right-hand side of the plane move downward, a rolling moment is created causing the vehicle to turn toward the left. Conversely, if the thrust deflectors 11 on the right-hand side of the plane move upward and the thrust deflectors 11 on the left-hand side of the plane move downward, a rolling moment is created causing the vehicle to turn toward the right. By super-imposing the pitch control action on top of the roll control action, both the pitch and roll degrees of freedom can be controlled simultaneously.

One embodiment of the present invention uses differential spanwise fan speed (fan rpm) for yaw and roll control. By using one or more motor controllers and more than one fan 1, the rpm of each fan can be controlled independently. If the rpm is increased on the fan (or fans) on one side of the plane and decreased on the opposite side, a differential thrust will result. This produces a yawing moment on the airplane. In addition, increased fan speed decreases the suction pressure on the top surface of the wing near the entrance to the fan ducting. This decrease in pressure locally increases the lift of the wing. The result of differential fan rpm is differential lift, and thus a rolling moment in addition to the yawing moment. Hence, it is possible to control the cross-flow fan wing system 100 (or enhance the other controls) using differential rpm.

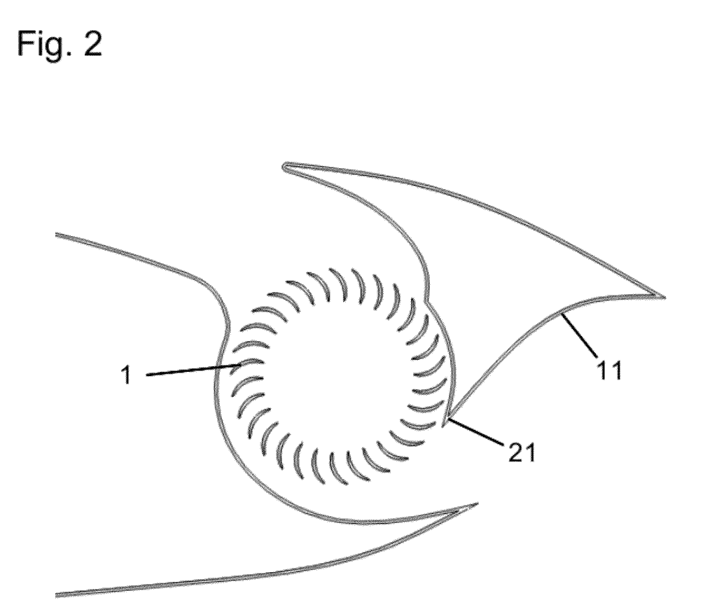

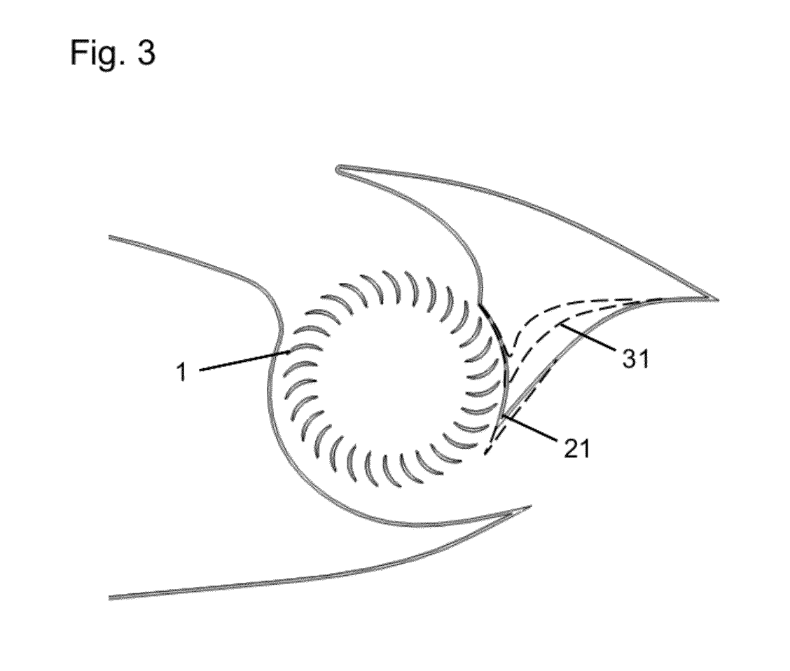

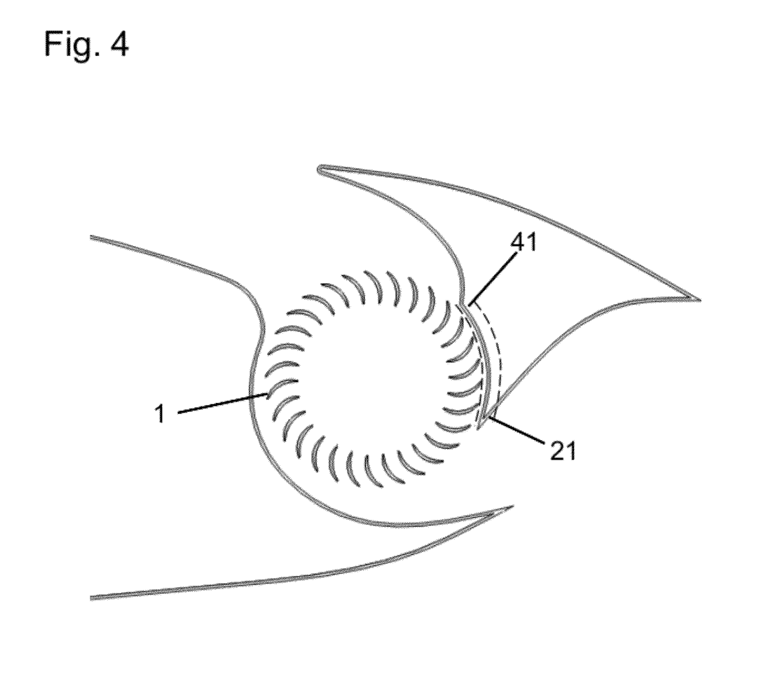

Another method of thrust vector angle and aircraft control is active control of the vortex wall 21 and internal housing geometry, as shown in FIGS. 2 through 4. Circumferential adjustment of the vortex wall, shown as dotted lines 31 in FIG. 3, alters the flow path through the cross-flow fan 1. This provides added control over the direction of the exhaust jet. Radial adjustment of the vortex wall gap 41, defined as the distance between the fan 1 and the vortex wall 21, alters fan efficiency and eccentric vortex positioning, which in turn changes both the thrust vector angle and fan mass flow rate. This effect provides a method for vehicle control through differential thrust and vector angle. In these cases, as the vortex wall gap 41 is changed, the angle the flow exits the cross-flow fan housing, as well as the torque input into fan 1 and thrust on the vehicle, are changed, allowing for control over all three angular degrees of freedom (pitch, roll, and yaw).

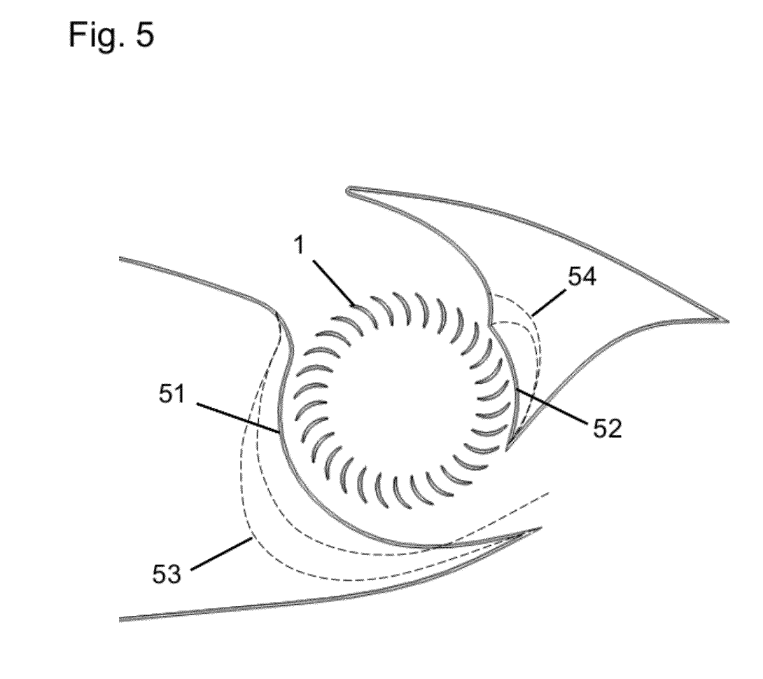

In addition, control over larger geometric features within the fan housing can also result in changes in forces and moments, allowing for control. For example, the lower housing 51 and the upper housing 52, shown in FIG. 5, can be dynamically altered in-flight via mechanical actuators to provide vehicle control. These geometry changes, shown in FIG. 5 by dotted lines 53, for the lower housing, and 54, for the upper housing, cause changes in the operating point of the fan 1. The operating point is the relationship between the flow rate and the total pressure rise through the fan. By shifting this relationship, through dynamic geometry modifications, the thrust output and torque input from the propulsion system are altered. This effect provides a means for vehicle control.

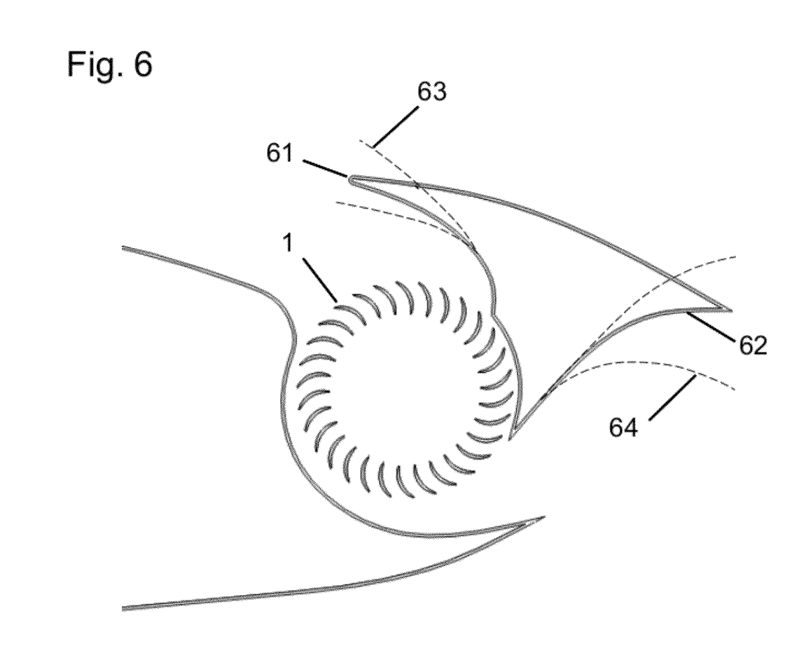

Dynamic adjustment of the inlet flap 61 and the outlet flap 62 provides another means for vehicle control via mass flow rate regulation through the fan 1. These geometry modifications are shown in FIG. 6 as dotted lines 63 for the inlet flap and dotted lines 64 for the outlet flap. By closing the flaps 61 and 62, the mass flow rate is reduced, while opening them results in increased mass flow rate. If this action is performed such that on one side of the vehicle the inlet and outlet flaps are opened, and simultaneously on the other side of the vehicle the inlet and outlet flaps are closed slightly, the result is increased flow rate on the former side and reduced flow rate on the latter. This in turn results in a spanwise differential in both lift and thrust, allowing for control over the roll and yaw degrees of freedom.

In addition, differential inlet height works in a similar way to conventional ailerons, providing for roll control through differential spanwise lift. By opening the inlet flap 61 on one side of the vehicle, and closing the inlet 61 on the opposite side of the vehicle, a rolling moment would result. Similarly, collective (i.e. simultaneous in the same direction) adjustment of the inlet 61 height produces a pitching moment, providing a means for vehicle pitch control.

In addition to control aspects of the design, control of the internal geometry (vortex wall 21, inlet flap 61, and outlet flap 62), provides a means to properly match the fan flow coefficient to the maximum efficiency point. Also, by opening the flaps 61 and 62, the mass flow rate increases, providing additional thrust (for example, at takeoff and landing). At high speed, these flaps can be partially closed to reduce mass flow rate, thus preventing flow choking from occurring through the fan 1.

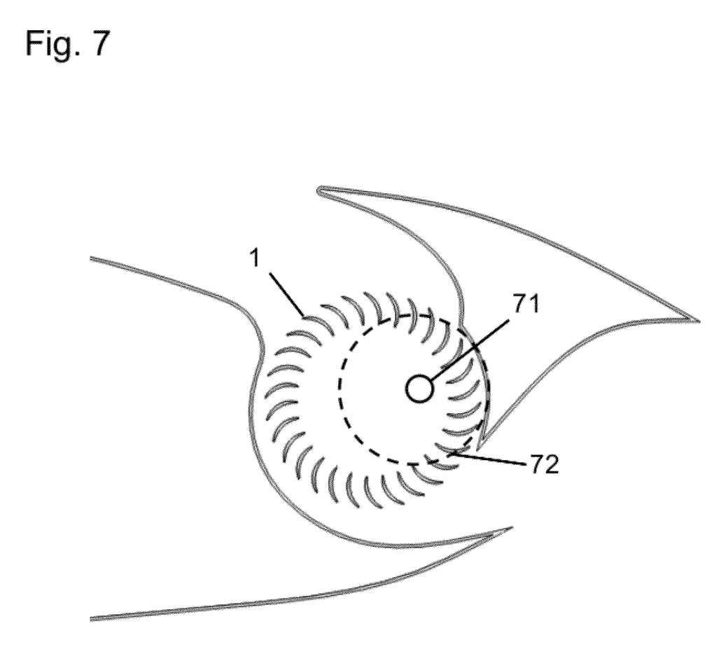

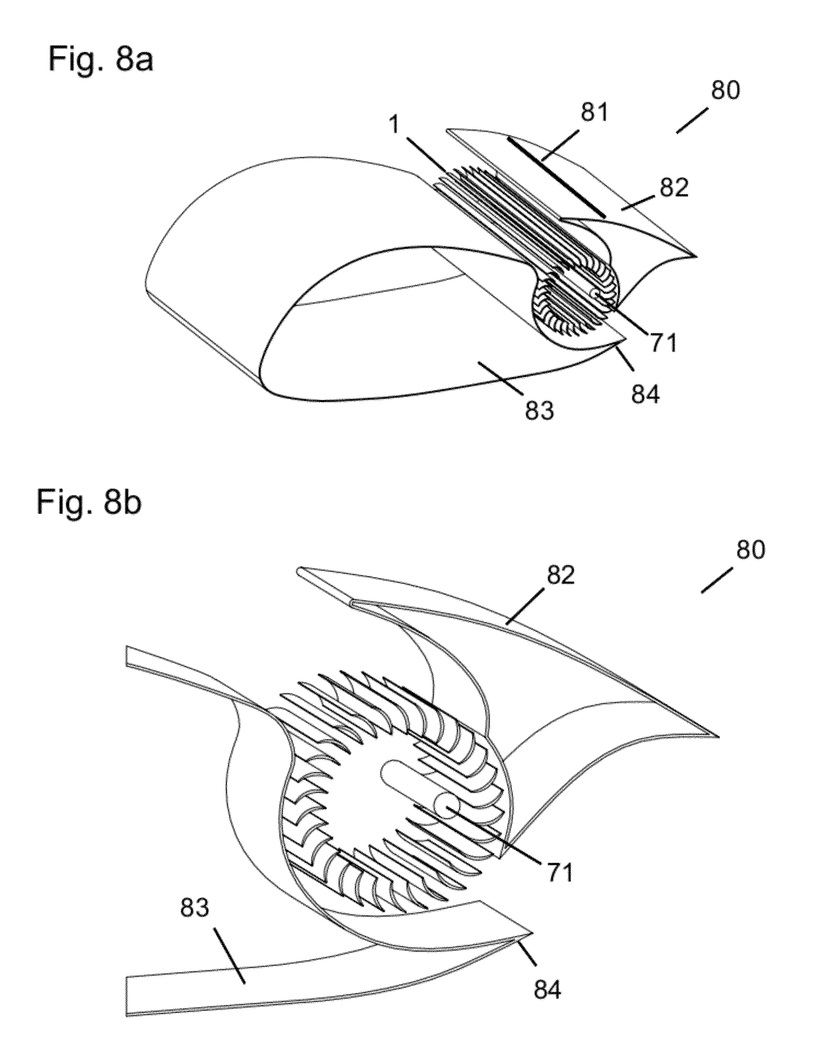

FIG. 7 shows a vortex tube 71. The vortex tube 71 is preferably porous, allowing the working fluid to penetrate through the surface of the tube. This is accomplished by using a porous material, perforating the surface of the vortex tube 71, or cutting directed channels in the surface of the vortex tube 71. Some materials that could be used for the vortex tube 71, include, but are not limited to, fiberglass, carbon fiber, PVC, aluminum, and steel. The vortex tube porosity preferably traverses the entire length of the fan through the vortex region, outlined by dotted line 72. Low pressure in the vortex region 72 draws flow into the vortex tube 71 from another location of higher pressure. This configuration has many potential uses. For example, by embedding a flow inlet strip 81 along the wing 80, as shown in FIG. 8a, and connecting this inlet strip 81 to the vortex tube 71, the vacuum provided by the fan vortex 72 draws flow from the wing surface into the flow inlet strip 81, into the vortex tube 71, and out into the main flow through the fan. By doing this, a large degree of boundary-layer flow control is provided for decreased drag and reduced chance of stall. This is an excellent method to eliminate flow separation on the cross flow fan shroud 82 and wing bottom surface 83, especially near the trailing edge 84. FIG. 8b shows a closeup near the trailing edge of the wing 80 with the vortex tube 71 installed. This vacuum could also be used to eliminate flow separation on any control surfaces that do not have cross-flow fans, or for any other use where a vacuum is needed onboard the vehicle (for example, instrumentation).

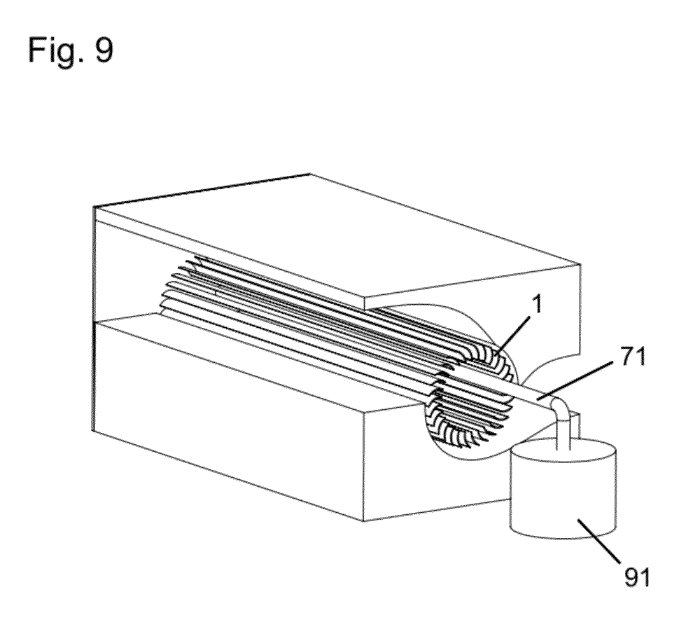

The vacuum provided by the vortex tube is also an ideal way to draw another gas or liquid (for example, water) into the airflow stream exiting the fan. An example of this is shown in FIG. 9, where a gas or liquid stored in a container 91 is drawn into the cross-flow fan 1, where it mixes with the air within the fan, and is then sprayed out with the main airflow out the exhaust. In addition to its use on aircraft, this mechanism may be useful in the field of farm crop spraying as an improvement to current technology, since it is already common in this application to utilize cross-flow fans to create an even spray over vegetation.

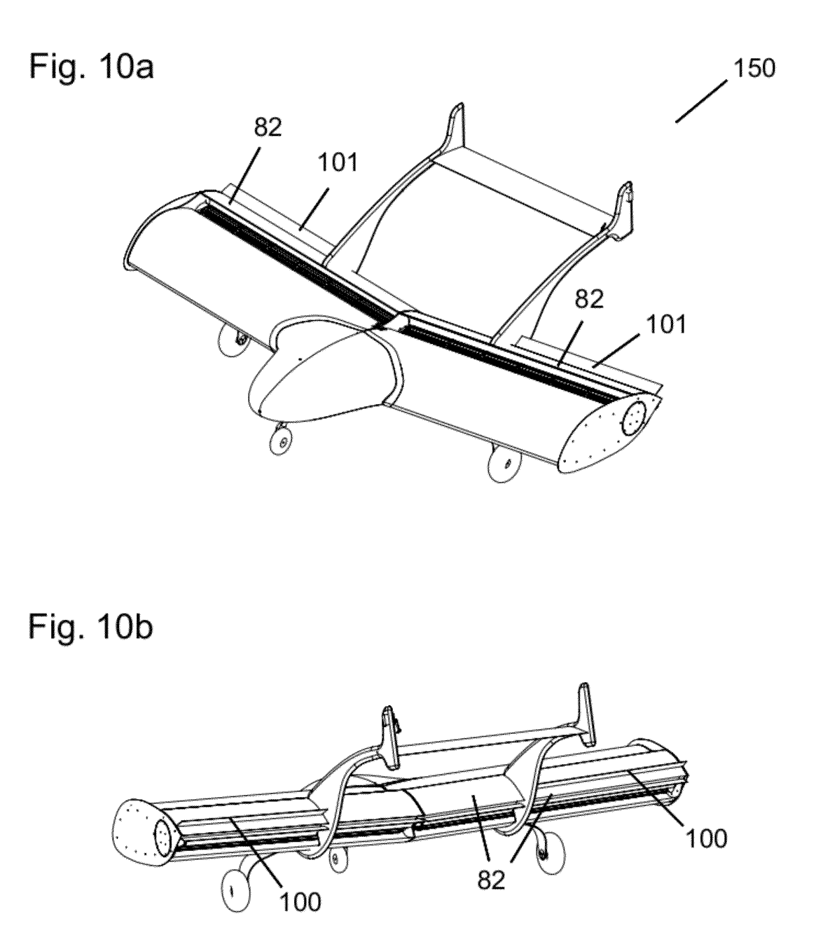

Actuated shroud panels 101 can be mounted on the fan housing shroud 82, as shown in FIGS. 10a and 10b, to improve control authority. In this configuration, collective adjustment of the shroud panels 82 provides pitch control for the system 150, while differential adjustment provides roll control for the cross-flow fan system 150.

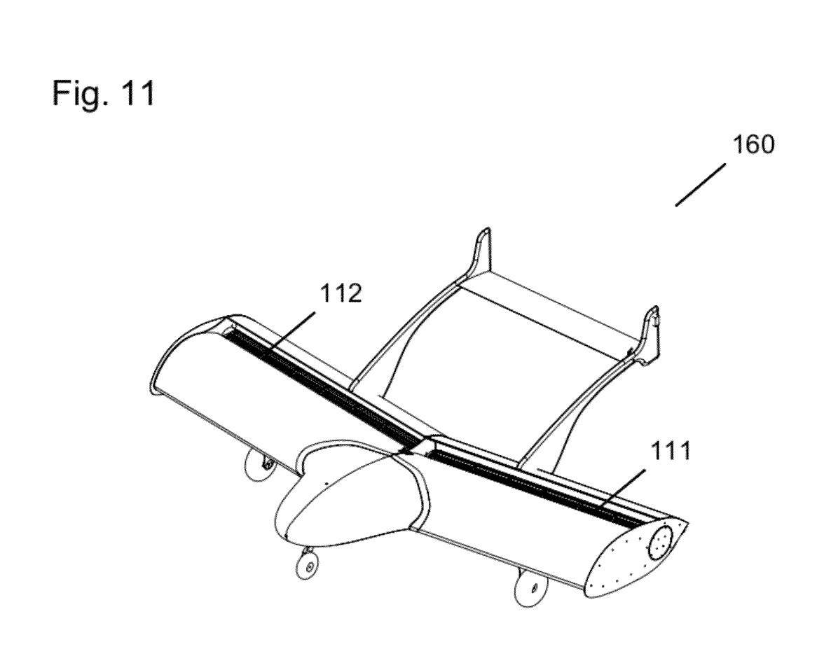

Several different methods utilize the cross-flow fan wing as a helicopter rotor. One embodiment of a cross-flow fan system 160 operating in a vertical flight (or helicopter) mode is shown in FIG. 11. Here, a wing contains multiple cross-flow fans 111 and 112 along its span. If power is supplied to fan 111, while at the same time fan 112 remains unpowered, a large rotating torque is created about the center of the vehicle/system. This causes the entire vehicle to rotate about its center, producing lift. Instead of the rotational torque supplied via a shaft, as in a conventional helicopter, here the entire vehicle comprises a rotor, which is powered by the distributed cross-flow fans. If it is desired that the vehicle take off vertically and then transition into conventional forward flight, the cross-flow fan wing 100 is used with one fan powered in vertical flight (such that the vehicle acts in a helicopter fashion), and then once a safe altitude is reached, the other fan is powered on, the rotational motion stops, and the vehicle begins to fly horizontally. These embodiments may be particularly useful in unmanned, pilotless vehicles.

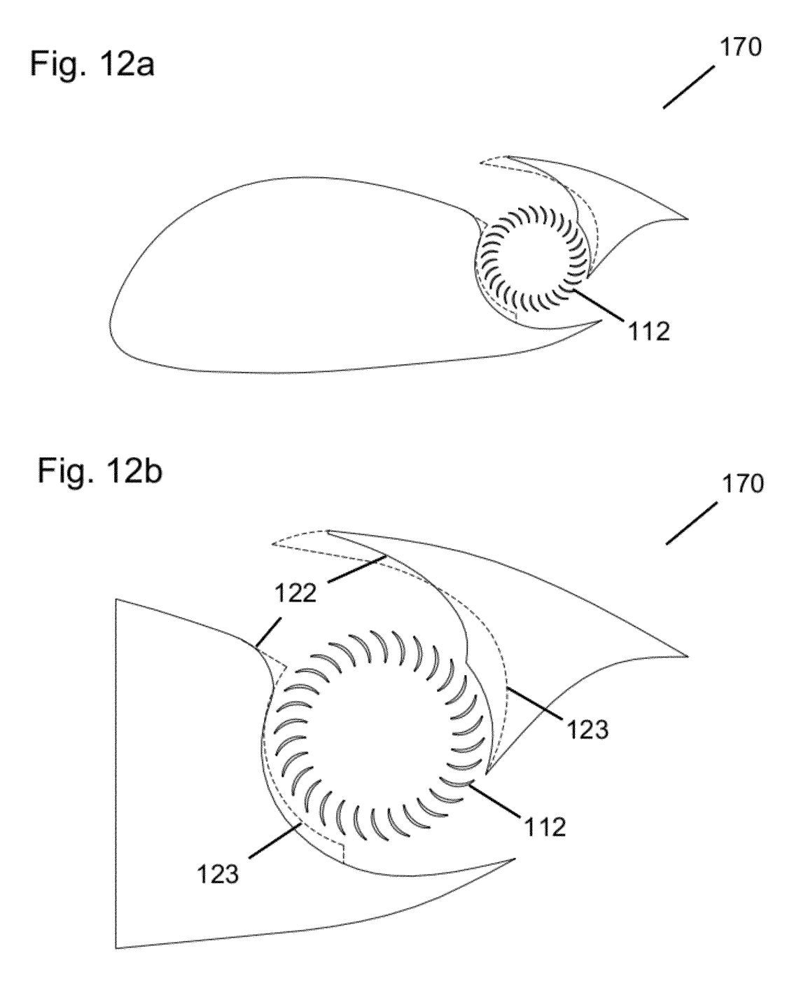

As an alternative to powering one of the fans for vertical takeoff and landing, with the other shut off, FIGS. 12a and 12b show an embodiment 170 of the cross-flow fan wing system 170 where all fans 111 and 112 can remain on throughout all flight regimes. Here, the fan internal housing 122 is altered with internal baffles and/or moving walls, shown in FIGS. 12a and 12b as dotted lines 123, to properly set up the flow path through fan 112. Here, both fans 111 and 112 remain on for vertical flight and rotate in the same direction. The difference lies in that the housing geometry 122 on one side of the vehicle is dynamically adjusted to that denoted by the dotted lines 123. By doing this, the direction of the flow through the fan is reversed on the side of the plane corresponding to internal geometry 123, creating thrust in opposite directions on each side of the vehicle. The result is a large torque, and subsequent spinning of the vehicle about its center, which produces lift. Once the vehicle has reached a safe altitude, geometry 123 is dynamically adjusted back to geometry 122, thus eliminating the vehicle spinning, and causing the vehicle to translate in an airplane mode.

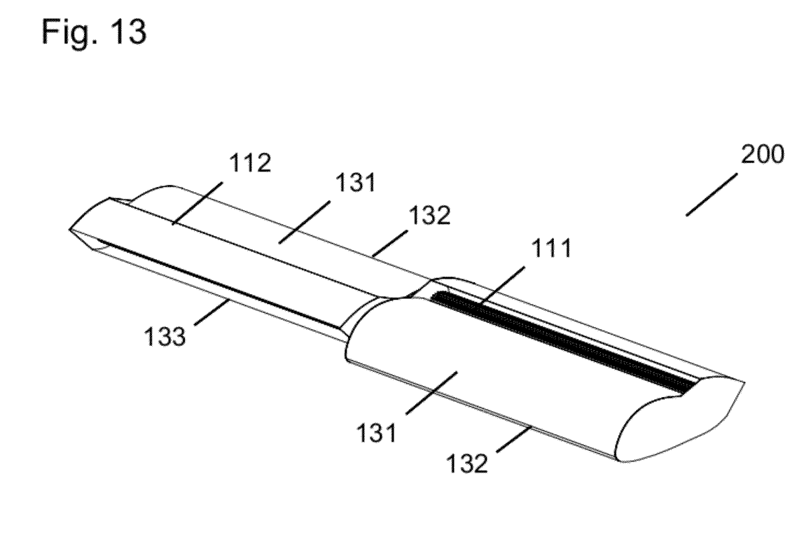

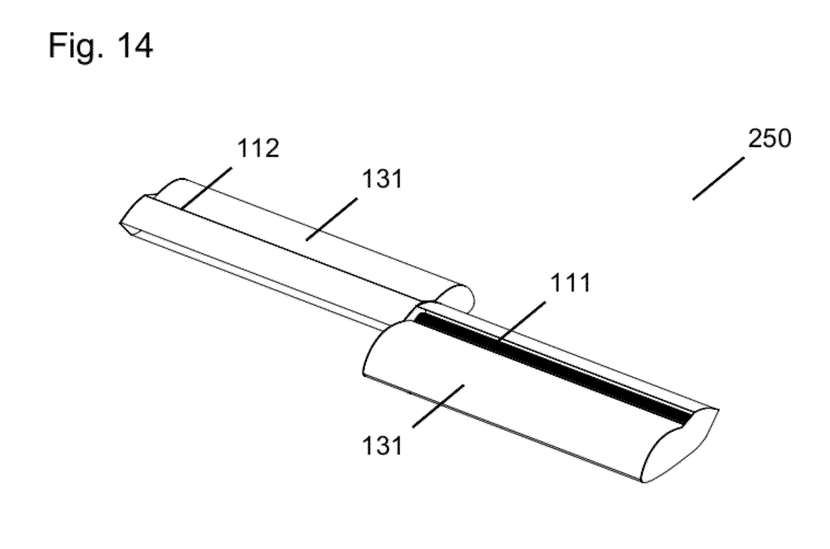

FIG. 13 shows another embodiment of a vertical takeoff and landing cross-flow fan wing system 200. Here, two cross-flow fan wings 131 face opposite directions and the system can act as a rotary wing propulsion system. Power is supplied to the fans in approximately equal amounts. Each wing 131 produces thrust, but in opposite directions, which causes the entire cross-flow fan wing system 200 to spin about its center, similar to a helicopter rotor. When the rotor 200 spins, each wing 131 turns in the direction of its own leading edge 132. In this case, both fans are powered continuously. FIG. 13 shows a version of the cross-flow fan rotor 200 where the leading edge 131 of one wing is approximately in line with the trailing edge 133 of the opposite wing. An alternative embodiment of the cross-flow fan wing system 250 is shown in FIG. 14, where the cross-flow fans 111 and 112 are co-linear.

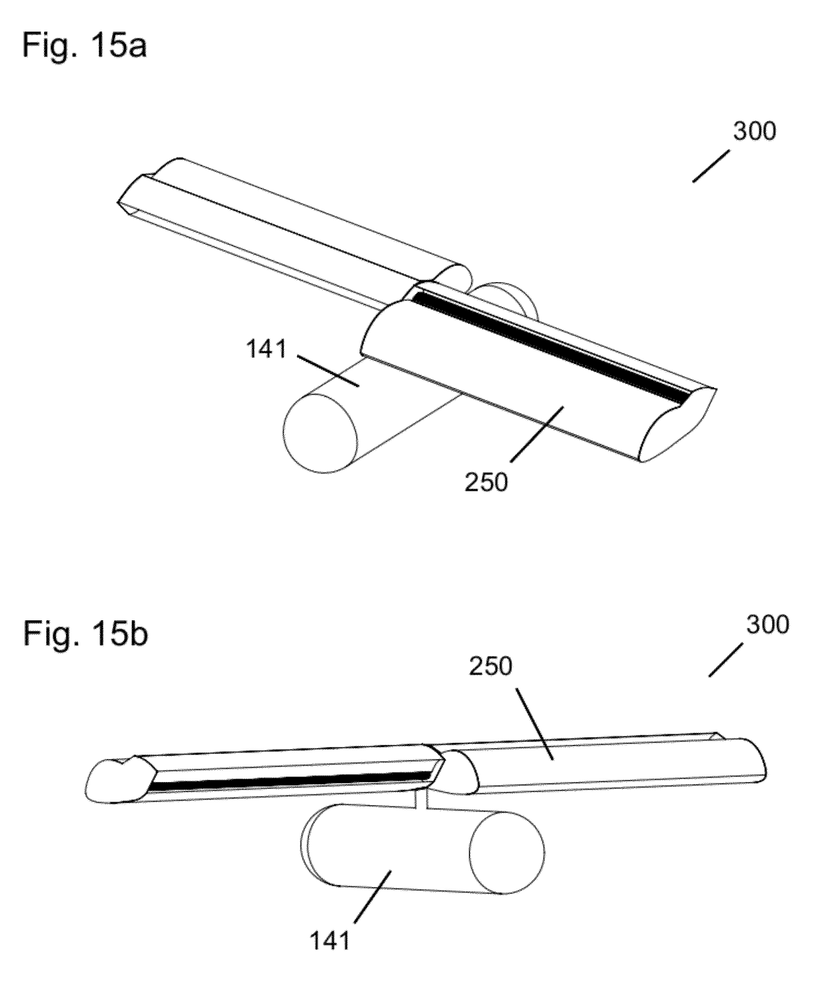

A benefit of the helicopter mode of flight is the capability to takeoff and land vertically without the need for a runway. This technology can also be incorporated into a helicopter configuration 300 with an additional fuselage 141, as shown in FIGS. 15a and 15b, where a conventional helicopter rotor is replaced with a distributed cross-flow fan wing rotor 250. In place of the cross-flow fan wing rotor 250, the rotor 200 could alternatively be used.

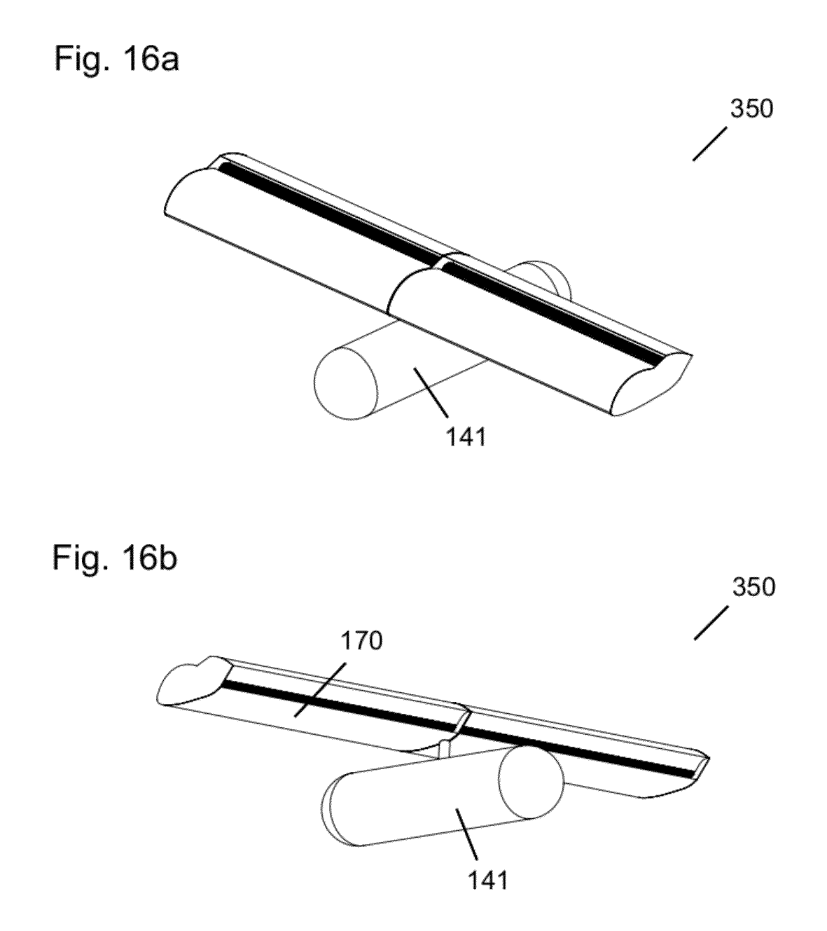

In another embodiment, FIGS. 16a and 16b show a wing 170 with an additional fuselage 141 mounted underneath. Using the housing changes shown in FIG. 12, the cross-flow fan wing rotor 350 acts in helicopter mode for vertical takeoff and landing, but can also be locked in a horizontal fashion, as shown in FIG. 16. Once locked in position, the vehicle is flown in an airplane mode of operation, with the distributed cross-flow fan wing providing lift, thrust, and flight controls.

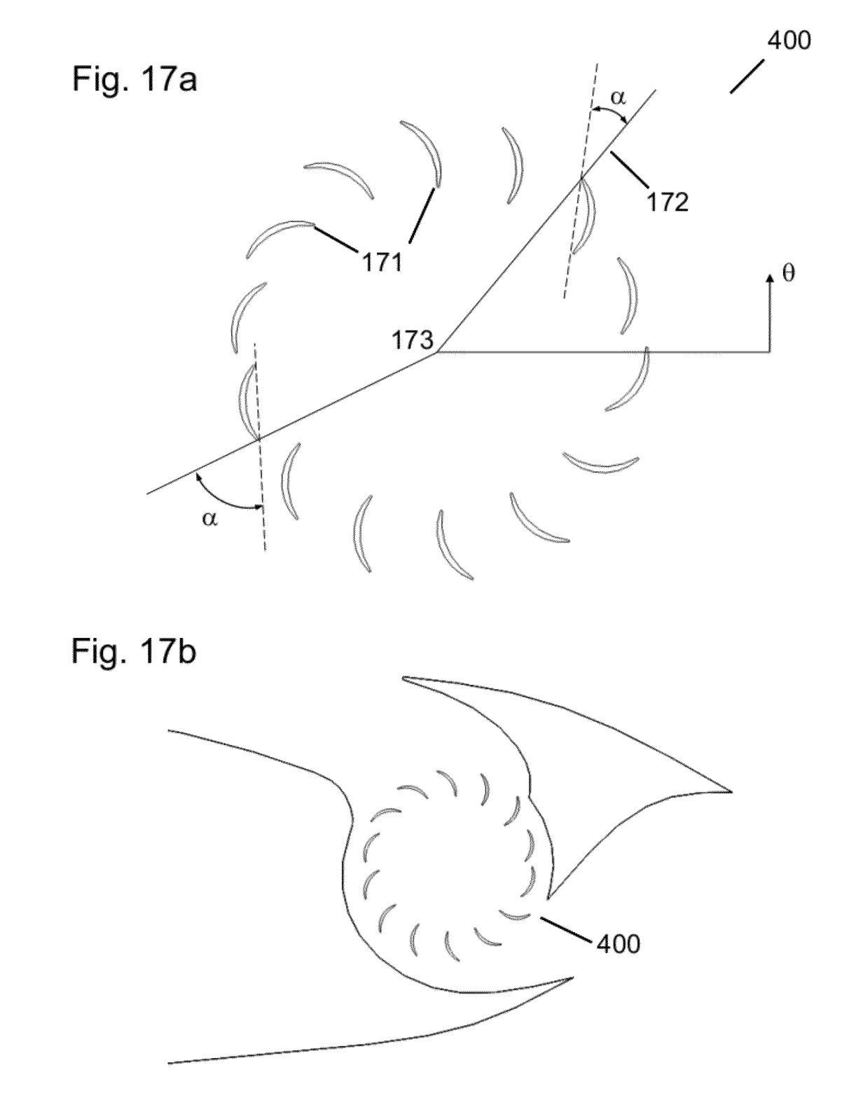

An oscillating blade fan 400, shown in FIGS. 17a and 17b, includes a cross-flow fan, where the individual fan blades 171 are allowed to rotate about their own axes through angle alpha (α) as the fan rotates through angle theta (θ). This permits the fan blades to rotate back and forth. In contrast, in a conventional cross-flow fan, the blades are fixed in place (that is, their angle α relative to a radial line 172 drawn from the center of the fan 173 to the periphery is constant). This embodiment includes a control system to alter a local blade incidence as a function of rotation angle such that the fan blades rotate back and forth within the wing propulsion system. An advantage of the oscillating blade fan 400 is that the flow field itself can be altered for improved fan efficiency and control of the flow direction. Improvements in efficiency are achieved by aligning the blades 171 for optimum flow incidence, defined as the angle of the blade relative to the local air flow direction. If the incidence angle is improved, particularly in the primary vortex and secondary vortex regions of the fan, the potential exists for substantial efficiency improvements up to 10-20%. If the blades are aligned perfectly with the local flow at every point, efficiencies greater than 90% can be achieved. The blade incidence angles will most likely be such that in the vortex regions the blades will be turned so that they are aligned nearly in the direction of rotation (i.e. in the tangential direction). This reduces the drag on the blades in these regions, thus improving efficiency. The application of this technology to a distributed cross-flow fan wing, as shown in FIG. 17b, increases aircraft efficiency in flight, decreasing fuel burn. Active control of the blade angle α can also provide aircraft control by altering the thrust vector angle (for pitch and roll control).

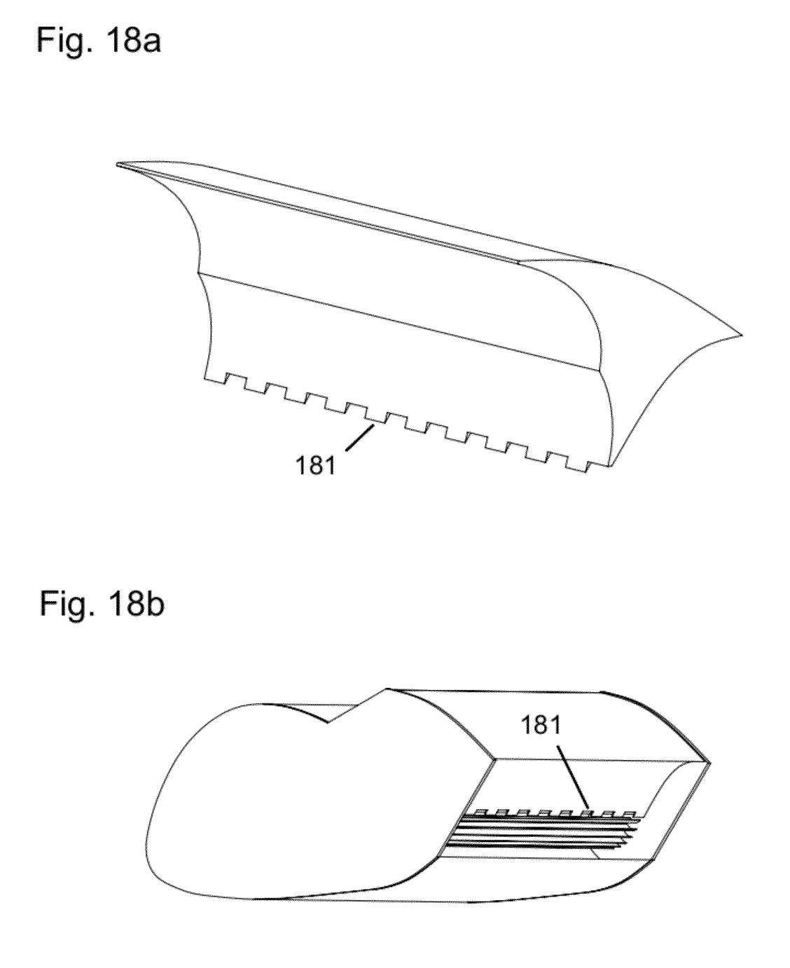

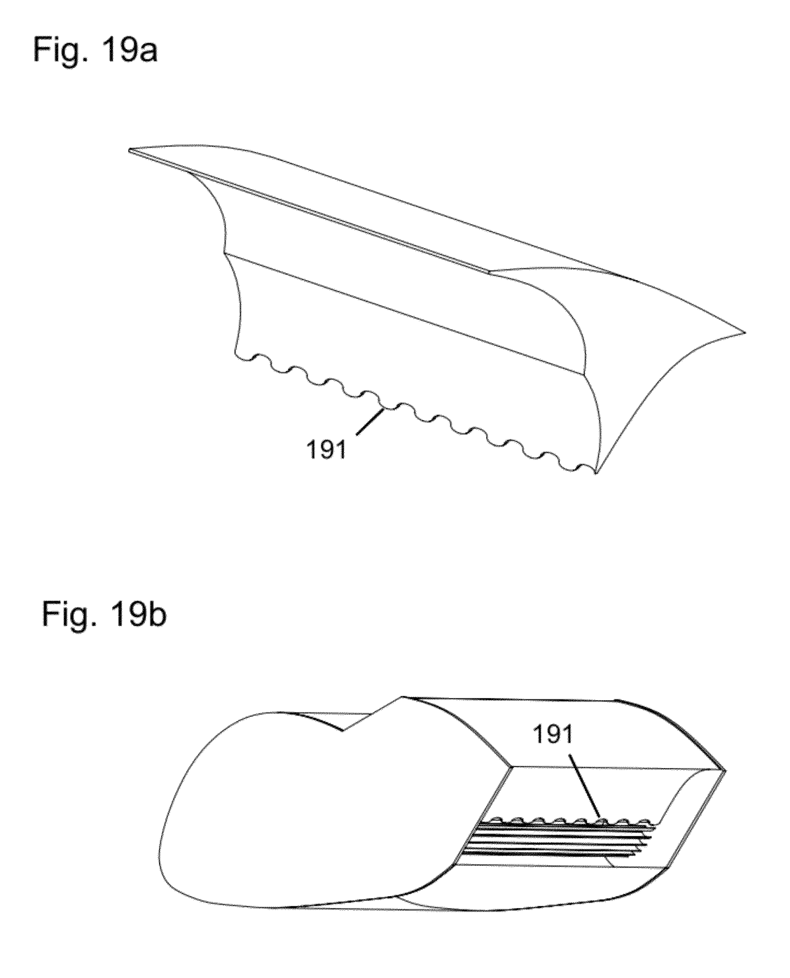

By incorporating a wavy vortex wall geometry, as shown in FIGS. 18a and 18b, the tonal noise emitted from the fan (produced at the blade passage frequency) is reduced. The variable geometry of the vortex wall 181 causes the blades to pass by the vortex wall at slightly different times, thus creating a frequency spectrum with a wider peak frequency, but at lower sound pressure level. That is, instead of a single very loud frequency being emitted from the fan, multiple frequencies at reduced loudness are produced. FIGS. 18a, 18b, 19a and 19b show representative geometries for the wavy vortex wall. The wall geometry can have a square-wave form 181 (FIGS. 18a and 18b), a sine-wave form (FIGS. 19a and 19b), or any other shape cut into the vortex wall including, but not limited to triangular, saw-tooth, and random fluctuations. By using more than two vortex wall heights along the spanwise direction, multiple sound frequencies are created. Furthermore, careful shaping of the wavy vortex wall provides sound interference effects for further noise reduction.

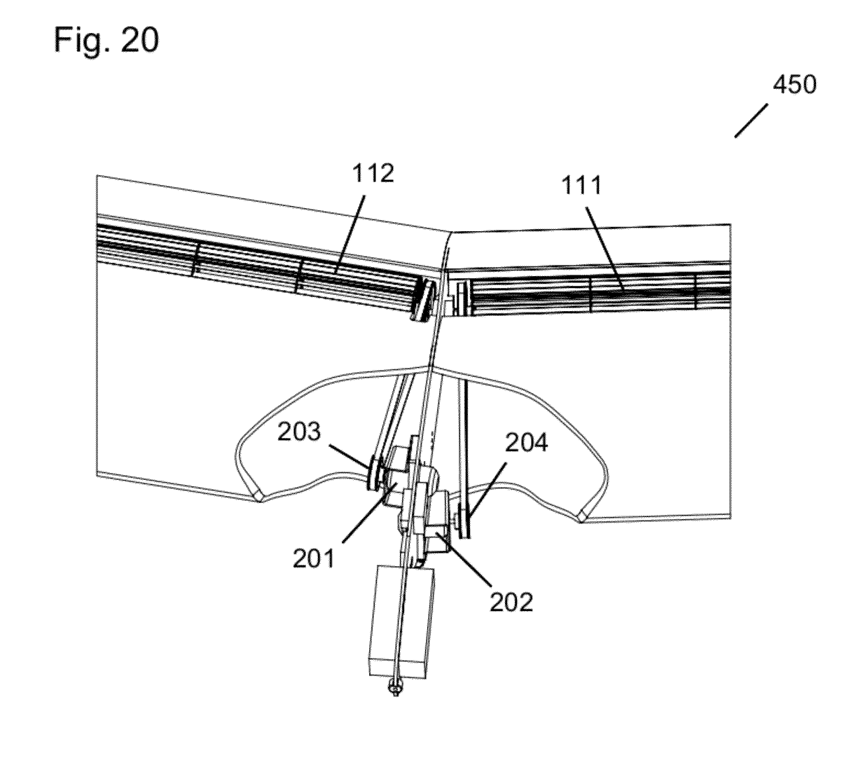

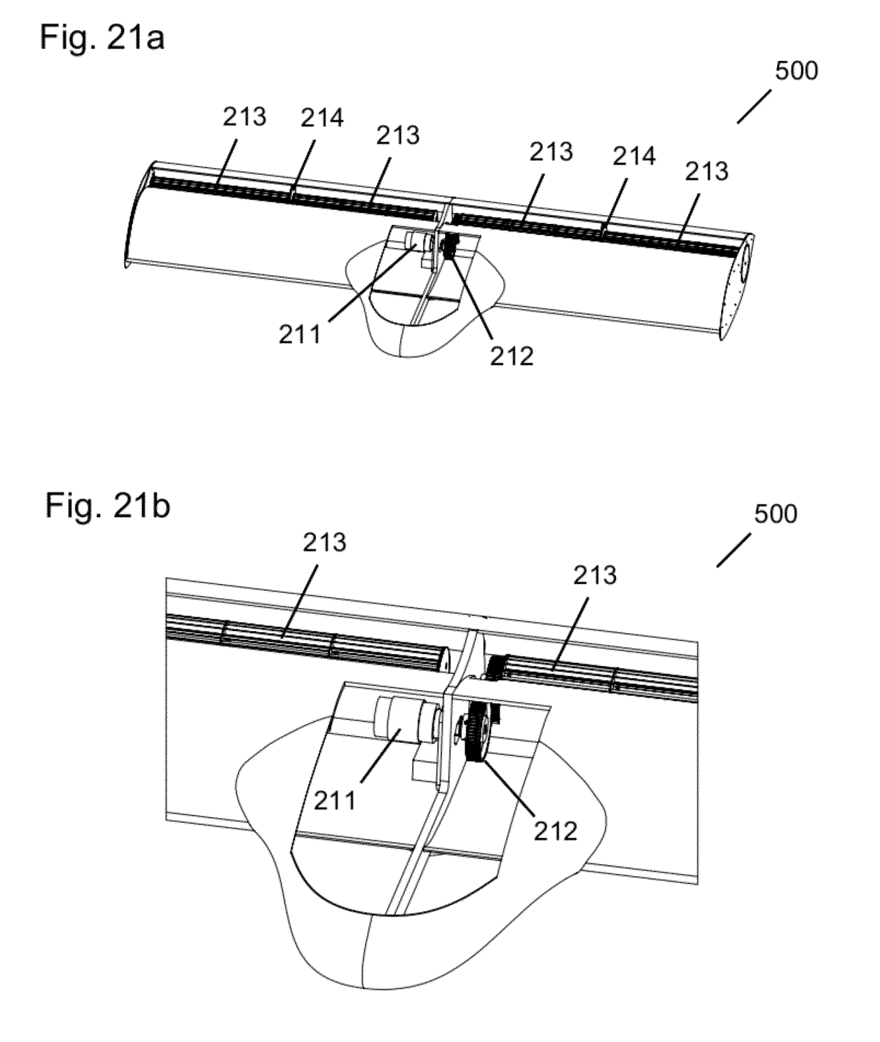

Several options exist for driving the cross-flow fans in the distributed cross-flow fan wing. One option is to use fans driven by electric motors and a pulley system. A single or multiple motors can be used to drive a single or multiple pulleys. FIG. 20 shows a configuration of a cross-flow fan wing system 450 with two electric motors 201 and 202 driving two independent pulley and belt systems 203 and 204, which are in turn driving two independent fans 112 and 111, respectively. FIGS. 21a and 21b show a configuration with a single electric motor 211 driving a single pulley system 212, which in turn is driving multiple cross-flow fans 213. In FIG. 21a, the cross-flow fan wing system 500 includes four cross-flow fans 213. In between the fans 213 on each side of the vehicle 500 are support plates 214, which allow for a longer wingspan by permitting additional fans 213 to be utilized. While four fans are shown in FIG. 21a, additional fans can be included in the system within the spirit of the present invention.

The advantage of having individual motors for each fan (or side of the vehicle) is that the speed of each fan can be controlled independently, allowing for yaw control via differential thrust. The advantages of a single drive motor and pulley system are simplicity and cost. Certainly if additional fans are used (for example, four fans instead of two), individual motors can be installed for each fan giving even greater control authority, as well as redundancy in the case of failure of one of the motors and/or fans.

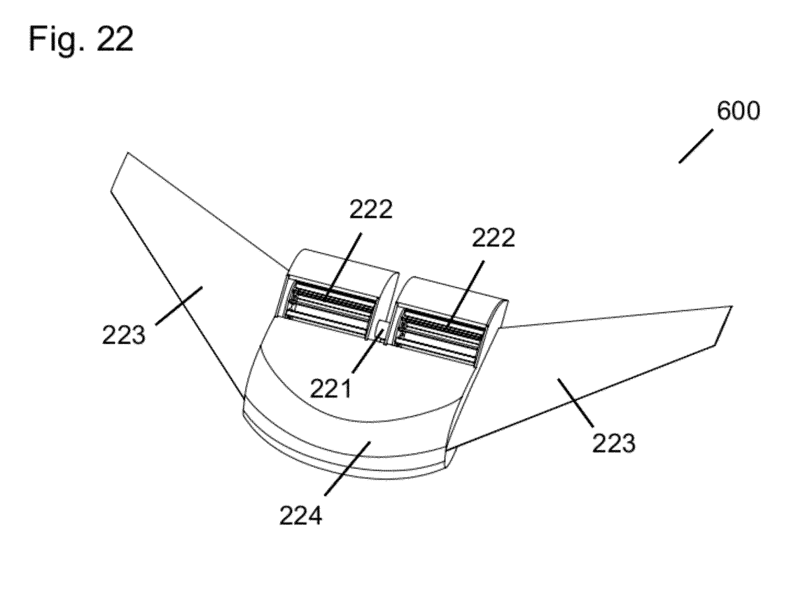

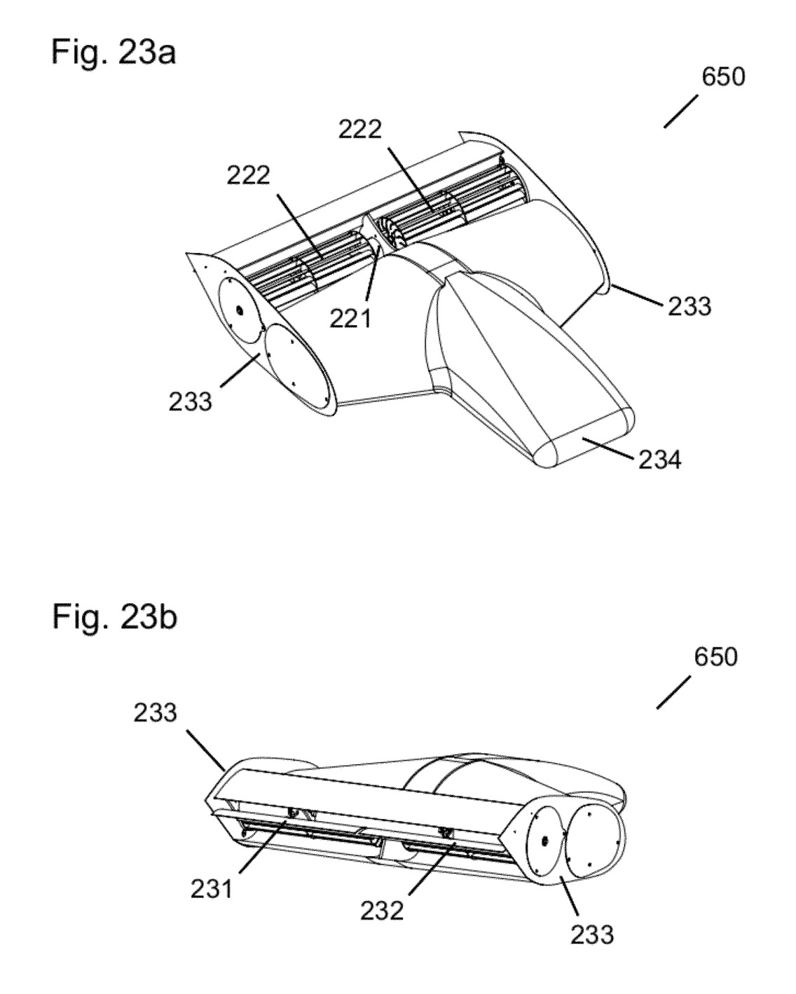

As an alternative to pulley systems to drive the fans, one or more electric motors can be installed in-between the fans, with a direct-drive or geared connection from the motor shaft to the fan hubs. This configuration is shown in FIGS. 22, 23a and 23b. In FIG. 22, a motor 221 is mounted in-between the fans 222 within the cross-flow fan wing system 600. Wing extensions 223 are attached to the center cross-flow fan wing section 224. An alternate embodiment of the cross-flow fan wing system 650 is shown in FIGS. 23a and 23b, where the wing extensions are not used. In this configuration, all of the vehicle controls come from collective and differential vectored thrust via the thrust deflectors 231 and 232. In addition, wing tip plates 233 can optionally be used to improve lateral stability and reduce induced drag on the vehicle. The tip plates also decrease ingestion of tip vortex flow into the fans, resulting in an increase in the spanwise uniformity of flow into the fans, improving the efficiency of the cross-flow fan propulsion. Some advantages of the configurations shown in FIGS. 22, 23a and 23b are simplicity, reduced parts, and increased reliability.

Furthermore, by placing weight (for example, cargo, the cockpit, passengers, fuel, the engine) in the nose 234 of the vehicle, shown in FIG. 23a, the pitch stability is improved. The addition of a nose to the distributed cross-flow fan wing allows the weight to be placed further forward, which moves the center of gravity forward. The result is improved pitch stability compared with a configuration without a nose and without the weight shifted forward.

For each of the configurations above, any other type of engine including, but not limited to gas-driven internal combustion engines and hybrid gas/electric engines, can be substituted for the electric motors. Fuel can be in the form of batteries, fuel cells, gasoline, diesel fuel, or any other appropriate fuel.

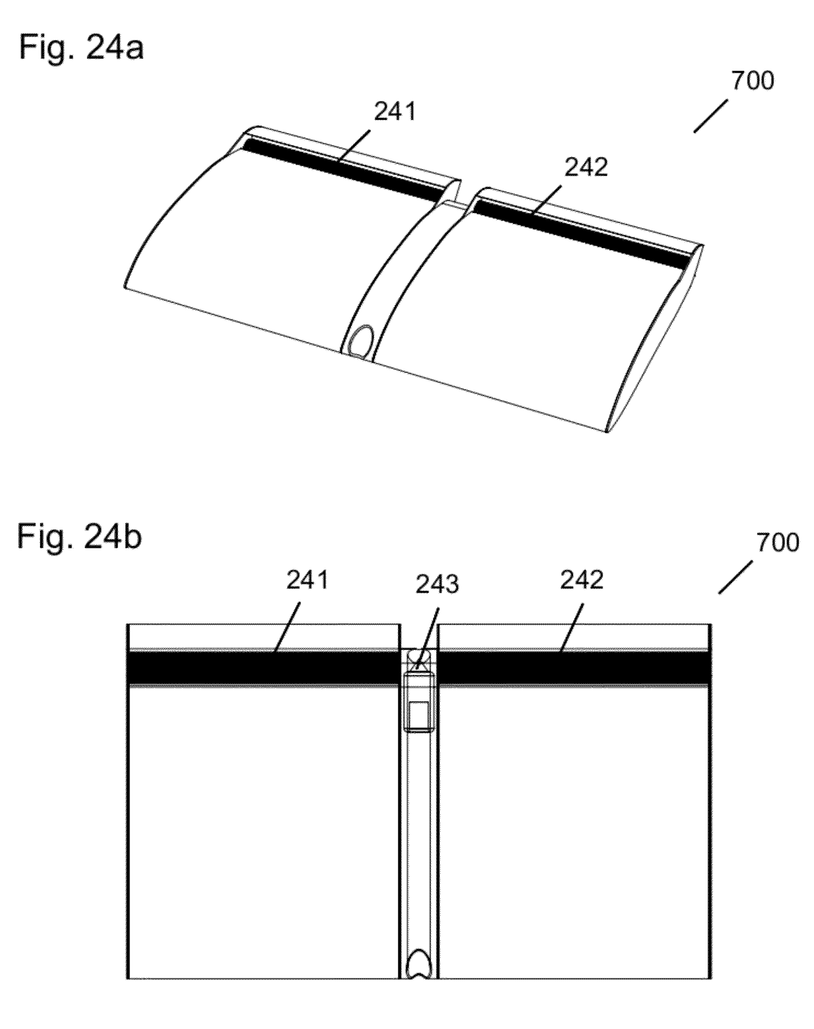

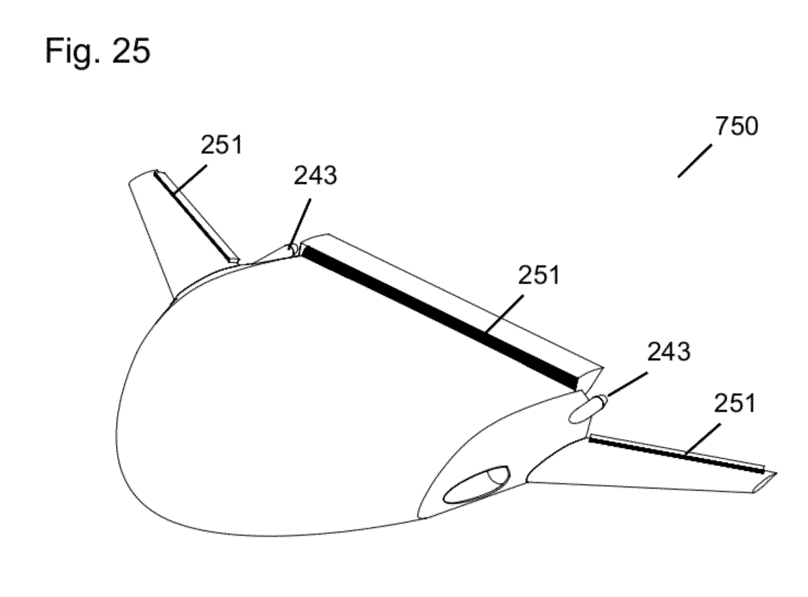

Other embodiments 700 for driving the cross-flow fan are shown in FIGS. 24a, 24b, and 25. In FIGS. 24a and 24b, a turbine engine 243 is used, where power is shafted, through appropriate gearing, to the cross-flow fans 241 and 242. In one preferred embodiment, the turbine engine 243 is a gas turbine engine (also called a combustion engine), although alternative turbine engines could be used. This embodiment preferably uses a small gas turbine engine, and shafts power off of it to drive the fans. This would be done in a manner similar to a turbo-prop engine, where a turbine stage supplies the power to the fan. The resulting system is called a turbo cross-flow fan propulsion system. FIG. 24b shows a schematic of such a system. As an alternative to using a turbine stage to turn a drive-shaft, a turbine 243 can be used to power an electric generator, which in turn provides electric power for electric motors that are used to drive the cross-flow fans. This is an alternative to using batteries in combination with electric motors. FIG. 25 shows an alternative embodiment 750 of this configuration, where multiple turbines 243 are used to power multiple distributed cross-flow fan propulsors 251.

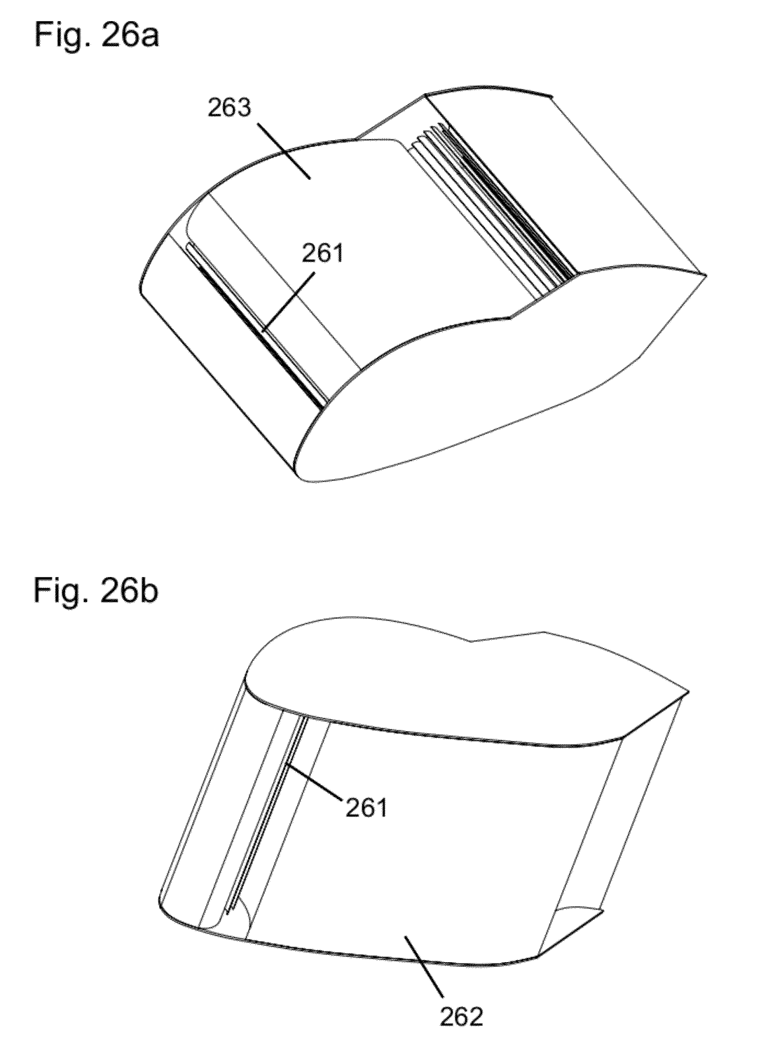

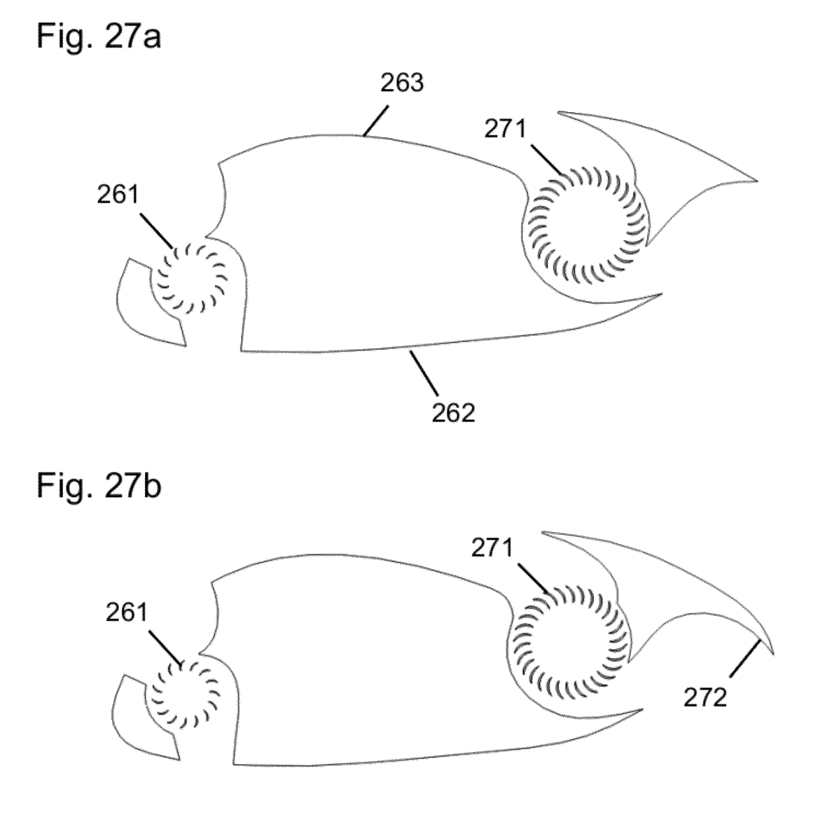

As shown in FIGS. 26a and 26b, a leading edge cross-flow fan 261 can be used to draw in flow from the wing bottom surface 262 and expel the fluid over the wing top surface 263 for flow control and incremental thrust. The air is preferably expelled approximately tangential to the wing top surface 263. This configuration is similar to a powered leading edge slat. For vertical takeoff and landing, the leading edge fan 261 ingests air from the wing top surface 263 and creates a downward jet by exhausting the high velocity jet toward the wing bottom surface 262. The air is preferably exhausted approximately perpendicular to the wing bottom surface 262. FIG. 27a shows a schematic of this configuration with the trailing edge cross-flow fan 271 exhausting straight backward. Alternatively, to increase vertical force in takeoff and landing, the trailing edge cross-flow fan 271 is directed downward by a thrust deflector 272, as shown in FIG. 27b. In forward flight, the leading edge fan can be used for increased lift (vertical takeoff mode), boundary-layer control (exhausting flow over wing top surface 263), or shut off completely. In the case where the fan 261 is turned off, the duct inlet and outlet for the fan 261 can be covered to reduce drag.

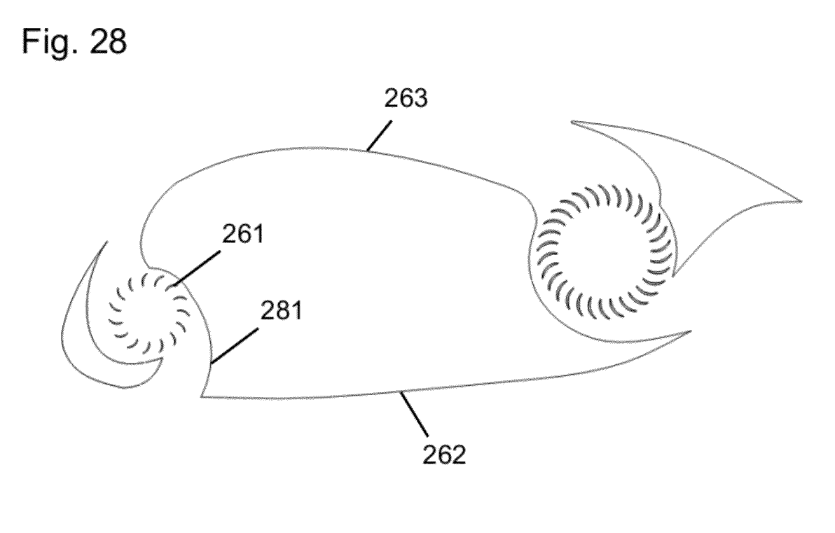

FIG. 28 shows a schematic of the housing geometry 281 near the leading edge cross-flow fan 261 corresponding to a horizontal-flight configuration. Here, the fan 261 is drawing air from the wing bottom surface 262 and expelling the air over the wing top surface 263. Additionally, in-flight it is possible to have the internal housing geometry 281 dynamic change from a vertical takeoff and landing configuration, as shown in FIG. 27, to an airplane (cruise) configuration, as shown in FIG. 28.

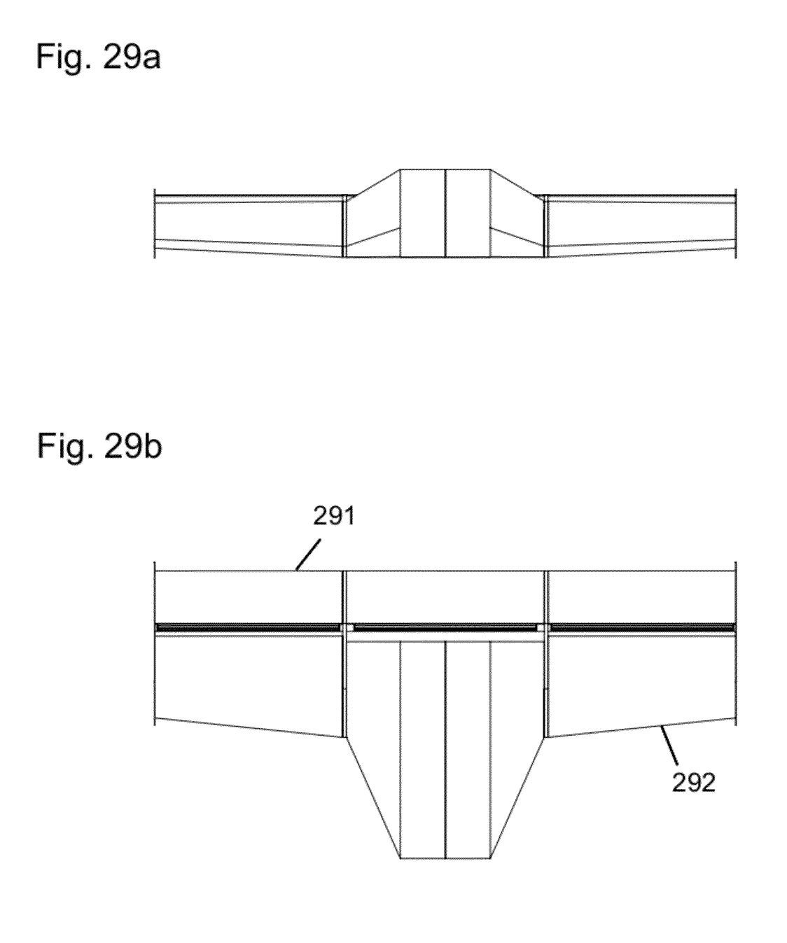

Aerodynamic efficiency can be improved by using a tapered distributed cross-flow fan wing, which increases the aspect ratio. This is often done on airplanes. In the case of a cross-flow fan propelled aircraft, it is possible to taper the wings, whereby the wing root is wider than the wing tip. One option is to use a leading-edge taper, as shown in FIGS. 29a and 29b. In this embodiment, the trailing edge 291 is maintained straight, and the fan has a constant diameter. The fan housing does not taper spanwise; however, the front portion of the wing 292 tapers toward the wing tip. In this case, wing dihedral and wing taper are added to the aircraft wing design through shaping of the wing portion forward of the fan. The airfoil thickness can also be reduced to maintain constant or near-constant thickness-to-chord ratio.

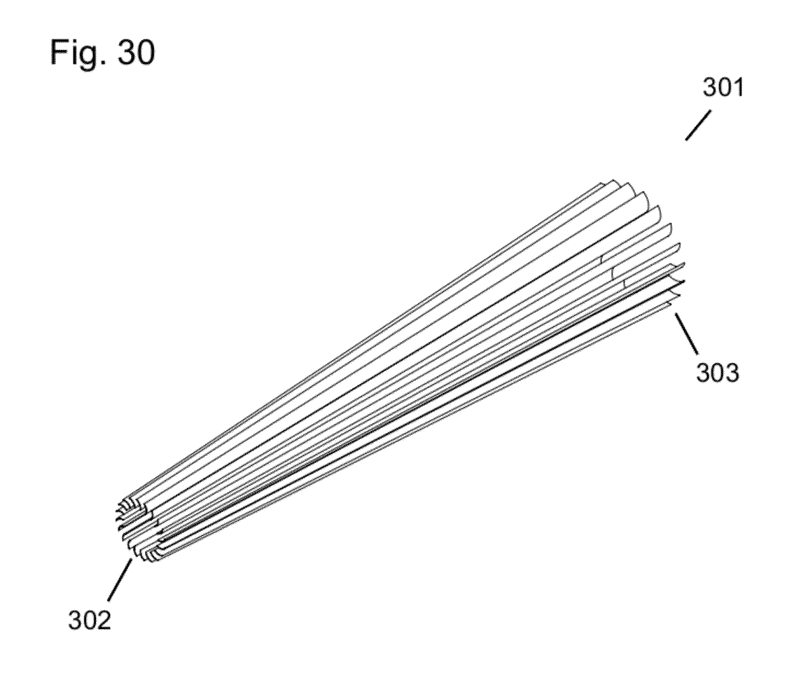

An additional option is to taper the fan diameter and fan housing as the wing tapers, maintaining a more uniform fan to airfoil thickness along the span. A tapered cross-flow fan 301 is shown in FIG. 30. Here, the fan diameter at a first fan end 302 is smaller than the fan diameter at a second fan end 303.

Within the framework of the distributed cross-flow fan wing, several different aircraft designs can be implemented. For example, the wing can be straight or swept, and can have dihedral built in for additional roll stability. Sweep and dihedral can be implemented by aligning each wing at a set sweep and dihedral angle. In a preferred embodiment, the fans are set at the sweep and dihedral angles as the wing. This embodiment is shown in FIG. 1.

In addition to aerial vehicles, the distributed cross-flow fan wing works for underwater applications. An example of an underwater cross-flow fan wing vehicle is shown in FIGS. 23a and 23b. The thick airfoil section provides an optimal configuration for a pressure vessel, which is necessary for structural stability when underwater, due to the high pressure environment. Unlike conventional underwater devices, the distributed cross-flow fan wing produces forces and moments (for thrust, lift, and control) in exactly the same way underwater as it does in the air. In essence, the distributed cross-flow fan wing “flies” underwater, with the primary difference coming in the direction of the lift vector. When flying in the air, the lift vector is directed upwards to counteract the downward force of gravity due to the weight of the aircraft. Underwater, the wing is flipped upside-down such that the lift force is downward. The lift force overcomes the buoyancy force when diving. To rise back to the water surface, the vehicle rotates 180 degrees such that the lift vector is now pointed to the surface. Optionally, the watercraft can also be naturally buoyant. That is, the vehicle will rise to the surface automatically if all propulsion systems are turned off. This provides increased safety and survivability. This configuration also provides greatly enhanced underwater maneuverability compared with conventional submersibles, since the vectored thrust capability of the distributed cross-flow fan wing works underwater for pitch and roll control. Additional ballast could also be added to help reduce this effect if so desired.

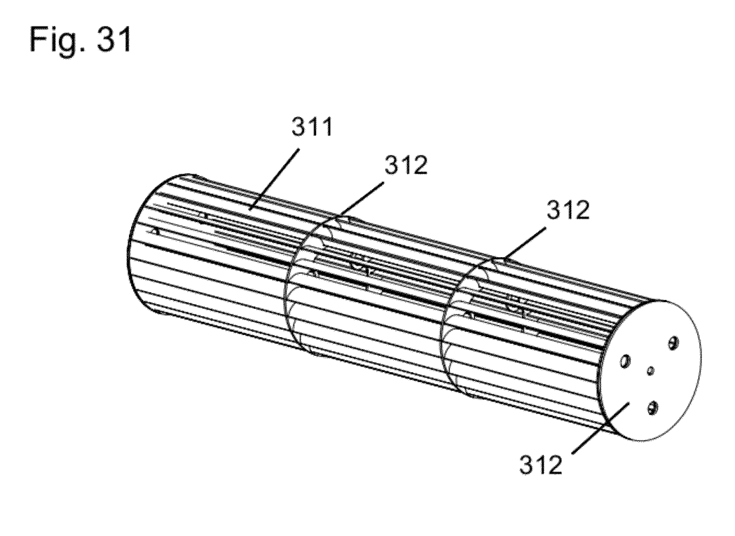

The cross-flow fans used in the distributed cross-flow fan wings described herein are preferably fabricated using pultruded carbon fiber blades 311 and carbon fiber support plates 312, as shown in FIG. 31. The support plates 312 are preferably fabricated with blade profile shaped holes. Fabrication of the complete fans is preferably accomplished by aligning the blades with the profile cut-outs in the support plates (both at the ends of the fan and with additional plates as needed along the span for decreased blade deflection). A custom fixture is used to align everything properly, and the blades are placed through the openings in the support plates. The support plates are then positioned evenly along the blade span, and finally adhesive (preferably an epoxy-based adhesive) is added to bond the entire assembly together. Although the pultruded material is preferably carbon fiber, any pultruded material could be used, including but not limited to, fiberglass and aramid, to form pultruded composite blades and/or support plates. In addition, non-pultruded extruded cross-section blades could be used, for example, injection molded blades or aluminum. FIG. 31 shows an example of a complete carbon-fiber cross-flow fan manufactured from pultruded carbon-fiber blades 311 and carbon-fiber end and support plates 312.

All of the patents, publications, and nonpatent references discussed herein are incorporated by reference in their entireties.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A propulsion wing system comprising:
an airfoil shaped wing body; and
at least one cross-flow fan at least partially embedded into the airfoil shaped wing body, comprising a motor, a rotor comprising a plurality of fan blades, and a cover surrounding the rotor and having an inlet and an outlet;
wherein the fan blades are pultruded blades.

2. The propulsion wing system of claim 1, wherein the pultruded blades are pultruded carbon fiber blades.

3. The propulsion wing system of claim 1, further comprising:
at least two thrust vectoring mechanisms located near a wing trailing edge for control of the direction of airflow from the outlet; and
a control system allowing simultaneous collective and differential control of the thrust vectoring mechanisms.

4. The propulsion wing system of claim 3, comprising at least two inboard thrust vectoring mechanisms and at least two outboard thrust vectoring mechanisms, wherein the inboard thrust vectoring mechanisms are only given collective inputs.

5. The propulsion wing system of claim 1, comprising at least two cross-flow fans and a control mechanism for independently regulating a fan speed of each cross-flow fan; wherein the control mechanism differentially controls the fan speed to produce a rolling, yawing, or pitching moment to control the wing body.

6. The propulsion wing system of claim 5, wherein when the control mechanism only activates a first cross-flow fan on a first side of the wing, creating a yawing moment.

7. The propulsion wing system of claim 5, wherein the control mechanism comprises at least one electric motor and a pulley and belt system that drives the propulsion wing system.

8. A cross-flow fan comprising:
a first support plate mounted at each end of the fan;
at least one second support plate mounted between the first support plates; and
a plurality of pultruded fan blades placed through openings in the first and second support plates.

9. The cross-flow fan of claim 8, wherein the pultruded fan blades comprise pultruded carbon fiber fan blades.

10. A method of manufacturing a cross-flow fan comprising a plurality of fan blades, comprising the step of manufacturing a plurality of fan blades for the cross-flow fan using a pultruded material.

11. The method of claim 10, wherein the pultruded material is a plurality of pultruded carbon fibers.

12. The method of claim 10, wherein the pultruded material is pultruded fiberglass or pultruded aramid.

13. The method of claim 10, further comprising the step of placing the cross-flow fan into a propulsion wing system comprising an airfoil shaped wing body.

14. The method of claim 10, further comprising the step of manufacturing a plurality of support plates using carbon fibers, wherein the support plates have a plurality of openings.

15. The method of claim 14, further comprising the steps of:
aligning the fan blades with the openings in the support plates;
positioning the support plates evenly along a blade span; and
bonding the fan blades to the support plates.

16. A propulsion wing system comprising:
an airfoil shaped wing body;
at least one cross-flow fan at least partially embedded into the airfoil shaped wing body, comprising a motor, a rotor comprising a plurality of fan blades, and a cover surrounding the rotor and having an inlet and an outlet; and
a dynamically adjustable internal housing adjacent to the fan blades.

17. The propulsion wing system of claim 16, wherein the dynamically adjustable internal housing comprises a vortex wall.

18. The propulsion wing system of claim 17, wherein the vortex wall can be adjusted in a direction selected from the group consisting of a circumferential direction and a radial direction.

19. The propulsion wing system of claim 16, wherein the dynamically adjustable internal housing comprises a lower housing and an upper housing, wherein the lower housing is dynamically adjustable.

20. The propulsion wing system of claim 16, wherein the dynamically adjustable internal housing comprises a lower housing and an upper housing, wherein the upper housing is dynamically adjustable.

21. The propulsion wing system of claim 16, wherein the dynamically adjustable internal housing comprises a lower housing and an upper housing, wherein the lower housing and the upper housing have a first geometry corresponding to a rotary wing mode of operation, and have a second geometry corresponding to a non-rotary wing mode of operation.

22. The propulsion wing system of claim 16, further comprising a fuselage mounted to the airfoil shaped wing body.

23. The propulsion wing system of claim 16, further comprising at least one flap on the airfoil shaped wing body selected from the group consisting of a dynamically adjustable inlet flap and a dynamically adjustable outlet flap.

24. A rotary wing propulsion system comprising:
a rotary wing comprising:
a first airfoil shaped wing body, comprising a first cross-flow fan comprising a first motor, a first rotor comprising a first plurality of fan blades, and a first cover surrounding the first rotor and having a first inlet and a first outlet; and
a second airfoil shaped wing body facing an opposite direction from the first wing body, comprising a second cross-flow fan comprising a second motor, a second rotor comprising a second plurality of fan blades, and a second cover surrounding the second rotor and having a second inlet and a second outlet.

25. The rotary wing propulsion system of claim 24, wherein a leading edge of the first wing body is approximately co-linear with a trailing edge of the second wing body, and a leading edge of the second wing body is approximately co-linear to a trailing edge of the first wing body.

26. The rotary wing propulsion system of claim 24, wherein the first cross-flow fan is co-linear with the second cross-flow fan.

27. The rotary wing propulsion system of claim 24, further comprising a fuselage mounted to the rotary wing.

28. A cross-flow fan system comprising:
a cross-flow fan comprising a motor, a rotor having plurality of fan blades, and a cover surrounding the rotor and having an inlet and an outlet; and
a vortex tube having a porous surface, wherein the vortex tube is placed within a vortex flow region of the cross-flow fan.

29. The cross-flow fan system of claim 28, wherein the vortex tubes is made of a porous material.

30. The cross-flow fan system of claim 28, wherein the porous surface comprises a plurality of perforations on the surface of the vortex tube.

31. The cross-flow fan system of claim 28, wherein the porous surface comprises a plurality of directed channels cut into the surface of the vortex tube.

32. The cross-flow fan system of claim 28, further comprising a wing coupled to the vortex tube such that the vortex tube draws working fluid from a surface of the wing.

33. The cross-flow fan system of claim 28, further comprising a tank or reservoir coupled to the vortex tube such that the vortex tube draws working fluid from the tank or the reservoir.

34. A propulsion wing system comprising:
an airfoil shaped wing body;
an oscillating cross-flow fan comprising a motor, a rotor having plurality of fan blades having a local blade incidence and a rotation angle, and a cover surrounding the rotor and having an inlet and an outlet; and
a control system that alters the local blade incidence as a function of the rotation angle of the fan blades.

35. A propulsion wing system comprising:
an airfoil-shaped wing body; and
a cross-flow fan at least partially embedded into the airfoil-shaped wing body, comprising a motor, a rotor having plurality of fan blades, a cover surrounding the rotor and having an inlet and an outlet; and a vortex wall adjacent to the fan blades and having a variable geometry.

36. The propulsion wing system of claim 35, wherein the variable geometry is selected from the group consisting of: a square-wave form, a sine wave form, a saw-tooth pattern, a triangular pattern, and a random pattern.

37. A propulsion wing system comprising:
an airfoil shaped wing body;
at least two cross-flow fans, each comprising a rotor comprising a plurality of fan blades, and a cover surrounding the rotor and having an inlet and an outlet;
a single motor driving all of the cross-flow fans; and
a single driveshaft that protrudes from both ends of the motor such that the motor is mounted in between the cross-flow fans.

38. The propulsion wing system of claim 37, wherein the motor drives a pulley and belt system.

39. The propulsion wing system of claim 37, further comprising at least one outboard wing attached to the airfoil shaped wing body.

40. A propulsion wing system comprising:
an airfoil shaped wing body;
at least one cross-flow fan at least partially embedded into the airfoil shaped wing body, comprising an electric motor, a rotor comprising a plurality of fan blades, and a cover surrounding the rotor and having an inlet and an outlet;
an electric generator electrically coupled to the electric motor; and
a turbine engine mechanically coupled to the electric generator.

41. The propulsion wing system of claim 40, wherein the turbine engine is a gas turbine engine.

42. A method of providing power to a propulsion wing system comprising an airfoil shaped wing body and at least one cross-flow fan at least partially embedded into the airfoil shaped wing body, comprising an electric motor, a rotor comprising a plurality of fan blades, and a cover surrounding the rotor and having an inlet and an outlet, comprising the steps of:
a) providing power to an electric generator using a turbine engine; and
b) providing power to the electric motor using the electric generator.

43. A propulsion wing system comprising:
an airfoil shaped wing body having a leading edge, a trailing edge, a top surface and a bottom surface;
a first cross-flow fan located near the trailing edge of the wing body and comprising a motor, a rotor comprising a plurality of fan blades, and a cover surrounding the rotor and having an inlet and an outlet; and
a second cross-flow fan located near the leading edge of the airfoil shaped wing body and comprising a motor, a rotor comprising a plurality of fan blades, and a cover surrounding the rotor and having an inlet and an outlet.

44. The propulsion wing system of claim 43, wherein the second cross-flow fan intakes air from a bottom surface of the wing body and expels the air toward a top surface of the wing body or intakes air from the top surface and expels the air toward the bottom surface.

45. A wing comprising:
an airfoil shaped wing body having a leading edge and a trailing edge; and
a cross-flow fan at least partially embedded into the airfoil shaped wing body, comprising a motor, a rotor having plurality of fan blades, and a cover surrounding the rotor and having an inlet and an outlet;
wherein the cross-flow fan remains parallel to a center line of the wing body and parallel to ground irrespective of dihedral, sweep, or taper of the leading edge.

46. The wing of claim 45, wherein the leading edge is shaped to add dihedral, sweep and taper to the wing.

47. A cross-flow fan comprising:
a rotor comprising a plurality of fan blades;
a motor powering the rotor; and
a cover surrounding the rotor and having an inlet and an outlet;
wherein the fan has a varying fan diameter along a span of the fan such that the fan is tapered.

48. An underwater vehicle comprising:
a propulsion wing system comprising:
a wing shaped body; and
a cross-flow fan propulsion mechanism at least partially embedded into the wing shaped body, comprising a motor, a rotor comprising a plurality of fan blades, and a cover surrounding the rotor and having an inlet and an outlet.
